(19) United States
(12) Patent Application Publication
(10) Pub. No.: US 2023/0084497 A1
(43) Pub. Date: Mar. 16, 2023

(54) THREE-DIMENSIONAL SEMICONDUCTOR MEMORY DEVICES, ELECTRONIC SYSTEMS INCLUDING THE SAME, AND METHODS OF FABRICATING THE DEVICES

(71) Applicant: Samsung Electronics Co., Ltd., Suwon-si (KR)

(72) Inventors: Jiyoung Kim, Seoul (KR); Moorym Choi, Yongin-si (KR); Junyoung Choi, Seoul (KR); Jungtae Sung, Seoul (KR); Sanghee Yoon, Suwon-si (KR); Wooyong Jeon, Anyang-si (KR)

(21) Appl. No.: 17/828,170

(22) Filed: May 31, 2022

(30) Foreign Application Priority Data
Sep. 14, 2021 (KR) 10-2021-0122385

(51) Int. Cl. H01L 23/00; H01L 25/065; H01L 25/18; H01L 25/00

(52) U.S. Cl. CPC H01L 24/08; H01L 25/0657; H01L 25/18; H01L 24/80; H01L 25/50; H01L 2224/08145; H01L 2224/80006; H01L 2224/80895; H01L 2224/80896; H01L 2924/1431; H01L 2924/14511

(57) ABSTRACT

A peripheral circuit structure may be formed on a first surface of a first substrate. A cell array structure may be formed on a first surface of a second substrate and may be attached to the peripheral circuit structure such that those first surfaces face each other. The cell array structure may be formed by forming a back-side via and a preliminary contact pad on the second substrate and forming a semiconductor layer. A hole may be formed to penetrate the semiconductor layer and to expose the preliminary contact pad and may be formed by removing an upper portion of the preliminary contact pad, thereby forming a contact pad separated from the semiconductor layer. The method may further include forming a stack on the semiconductor layer, an insulating layer on the stack, and a contact plug penetrating the insulating layer and connected to the contact pad.

### CROSS-REFERENCE TO RELATED APPLICATION

This U.S. non-provisional patent application claims priority under 35 U.S.C. § 119 to Korean Patent Application No. 10-2021-0122385, filed on Sep. 14, 2021, in the Korean Intellectual Property Office, the entire contents of which are hereby incorporated by reference.

### BACKGROUND OF THE INVENTION

The present disclosure relates to a three-dimensional semiconductor memory device, a method of fabricating the same, and an electronic system including the three-dimensional semiconductor memory device, and in particular, a three-dimensional semiconductor memory device including a peripheral circuit structure and a cell array structure, which are coupled to each other through bonding pads, a method of fabricating the same, and an electronic system including the three-dimensional semiconductor memory device.

A semiconductor device capable of storing a large amount of data may be used as a data storage of an electronic system. Higher integration of semiconductor devices may be beneficial to satisfy consumer demands for large data storing capacity, superior performance, and inexpensive prices. In the case of two-dimensional or planar semiconductor devices, since their integration is mainly determined by the area occupied by a unit memory cell, integration may be greatly influenced by the level of a fine pattern forming technology. However, the extremely expensive equipment used for fine patterns may set a practical limitation on increasing integration for two-dimensional or planar semiconductor devices. Thus, three-dimensional semiconductor memory devices including three-dimensionally arranged memory cells have recently been proposed.

### SUMMARY

Example embodiments of the inventive concept provide a three-dimensional semiconductor memory device with improved electrical characteristics and reliability and a method of fabricating the same.

Example embodiments of the inventive concept provide a three-dimensional semiconductor memory device and a simplified method of fabricating the same.

According to an embodiment of the inventive concept, a method of fabricating a three-dimensional semiconductor memory device may include forming a peripheral circuit structure on a first surface of a first substrate, forming a cell array structure on a first surface of a second substrate, and attaching the cell array structure to the peripheral circuit structure such that the first surface of the first substrate and the first surface of the second substrate face each other. The forming of the cell array structure may include forming a back-side via and a preliminary contact pad on the first surface of the second substrate, forming a lower semiconductor layer connected to (e.g., contacting) top surfaces of the back-side via and the preliminary contact pad, forming a penetration hole to penetrate the lower semiconductor layer and to expose the preliminary contact pad, the forming of the penetration hole being performed to remove an upper portion of the preliminary contact pad, thereby forming a contact pad separated from the lower semiconductor layer, forming a stack on the lower semiconductor layer, forming a first interlayer insulating layer on the stack, and forming a penetration contact plug to penetrate the first interlayer insulating layer and to be connected to the contact pad.

According to an embodiment of the inventive concept, a method of fabricating a three-dimensional semiconductor memory device may include forming a peripheral circuit structure on a first surface of a first substrate, forming a cell array structure on a first surface of a second substrate, and attaching the cell array structure to the peripheral circuit structure such that the first surface of the first substrate and the first surface of the second substrate face each other. The forming of the cell array structure may include forming a back-side via and a contact pad on the first surface of the second substrate, forming a lower semiconductor layer on the back-side via and the contact pad, forming a stack on the lower semiconductor layer, forming a first interlayer insulating layer on the stack, and forming a penetration contact plug to penetrate the first interlayer insulating layer and to be connected to the contact pad. The forming of the back-side via and the contact pad may include forming a second interlayer insulating layer on the second substrate, forming a first penetration hole and a second penetration hole to penetrate the second interlayer insulating layer, and forming a conductive material in the first penetration hole and the second penetration hole (e.g., filling the first penetration hole and the second penetration hole with the conductive material).

According to an embodiment of the inventive concept, a three-dimensional semiconductor memory device may include a first substrate, a peripheral circuit structure on the first substrate, and a cell array structure provided on the peripheral circuit structure. The cell array structure may include a cell array region and a cell array contact region. The cell array structure may include a second substrate, a stack between a first surface of the second substrate and the peripheral circuit structure, vertical channel structures provided in the cell array region to penetrate the stack, a back-side conductive pattern spaced apart from the stack with the second substrate interposed therebetween, a penetration contact plug provided in the cell array contact region to penetrate the second substrate and connected to the back-side conductive pattern, a back-side via protruding from a second surface of the second substrate, and a contact pad disposed at the same level as the back-side via and connected to the penetration contact plug.

According to an embodiment of the inventive concept, a three-dimensional semiconductor memory device may include a first substrate, a peripheral circuit structure on the first substrate, and a cell array structure provided on the peripheral circuit structure. The cell array structure may include a cell array region and a cell array contact region. The cell array structure may include a second substrate, a stack between a first surface of the second substrate and the peripheral circuit structure, vertical channel structures provided in the cell array region to penetrate the stack, a back-side conductive pattern provided on the cell array contact region and spaced apart from the stack with the second substrate interposed therebetween, a penetration contact plug provided in the cell array contact region to penetrate the second substrate, a contact pad disposed between the back-side conductive pattern and the penetration contact plug, and a penetration via connecting the back-side conductive pattern to the penetration contact plug. An interface between a bottom surface of the penetration via and a top surface of the penetration contact plug may be provided in the contact pad.

According to an embodiment of the inventive concept, an electronic system may include a three-dimensional semiconductor memory device including a first substrate, a peripheral circuit structure on the first substrate, and a cell array structure on the peripheral circuit structure, the cell array structure including a cell array region and a cell array contact region, and a controller, which is electrically connected to the three-dimensional semiconductor memory device through an input/output pad and is configured to control the three-dimensional semiconductor memory device. The cell array structure may include a second substrate, a stack between a first surface of the second substrate and the peripheral circuit structure, vertical channel structures provided in the cell array region to penetrate the stack, a back-side conductive pattern spaced apart from the stack with the second substrate interposed therebetween, a penetration contact plug provided in the cell array contact region to penetrate the second substrate and connected to the back-side conductive pattern, a back-side via protruding from a second surface of the second substrate, and a contact pad disposed at the same level as the back-side via and connected to the penetration contact plug.

According to an embodiment of the inventive concept, a method of fabricating a semiconductor device may include forming a cell array structure on a substrate and attaching the cell array structure to a peripheral circuit structure. The cell array structure is between the substrate and the peripheral circuit structure after the attaching. Forming the cell array structure may include forming a first insulating layer including a first hole and a second hole on the substrate, the first and second holes extending through the first insulating layer and exposing the substrate, forming a back-side via in the first hole and a preliminary contact pad in the second hole by forming portions of a conductive layer respectively in the first and second holes, forming a semiconductor layer extending on the first insulating layer and contacting the back-side via and the preliminary contact pad, forming a third hole extending through the semiconductor layer and exposing the preliminary contact pad, forming a contact pad by removing a portion of the preliminary contact pad through the third hole, forming a stack on the semiconductor layer, forming a second insulating layer on the stack, and forming a contact plug extending through the second insulating layer and contacting the contact pad.

### BRIEF DESCRIPTION OF THE DRAWINGS

FIG. 1 is a diagram schematically illustrating an electronic system including a three-dimensional semiconductor memory device according to an embodiment of the inventive concept.

FIG. 2 is a perspective view schematically illustrating an electronic system including a three-dimensional semiconductor memory device according to an embodiment of the inventive concept.

FIGS. 3 and 4 are sectional views, which are respectively taken along lines I-I′ and of FIG. 2 to illustrate a semiconductor package including a three-dimensional semiconductor memory device according to an embodiment of the inventive concept.

FIG. 5 is a plan view illustrating a three-dimensional semiconductor memory device according to an embodiment of the inventive concept.

FIGS. 6A and 6B are sectional views, which are respectively taken along lines I-I′ and II-II′ of FIG. 5 to illustrate a three-dimensional semiconductor memory device according to an embodiment of the inventive concept.

FIG. 7A is an enlarged sectional view illustrating a portion ‘A’ of FIG. 6A.

FIGS. 7B, 7C, and 7D are enlarged sectional views, each of which illustrates a portion of a three-dimensional semiconductor memory device according to an embodiment of the inventive concept.

FIGS. 8A, 14A, and 15A are sectional views, which are taken along the line I-I′ of FIG. 5 to illustrate a method of fabricating a three-dimensional semiconductor memory device according to an embodiment of the inventive concept.

FIGS. 8B, 14B, and 15B are sectional views, which are taken along the line II-II′ of FIG. 5 to illustrate a method of fabricating a three-dimensional semiconductor memory device according to an embodiment of the inventive concept.

FIGS. 9A, 10A, 11A, 12A and 13A are sectional views, which are taken along a line III-III′of FIG. 5 to illustrate a method of fabricating a three-dimensional semiconductor memory device according to an embodiment of the inventive concept.

FIGS. 9B, 10B, 11B, 12B and 13B are sectional views, which are taken along a line IV-IV′ of FIG. 5 to illustrate a method of fabricating a three-dimensional semiconductor memory device according to an embodiment of the inventive concept.

### DETAILED DESCRIPTION

Example embodiments of the inventive concept will now be described more fully with reference to the accompanying drawings, in which example embodiments are shown.

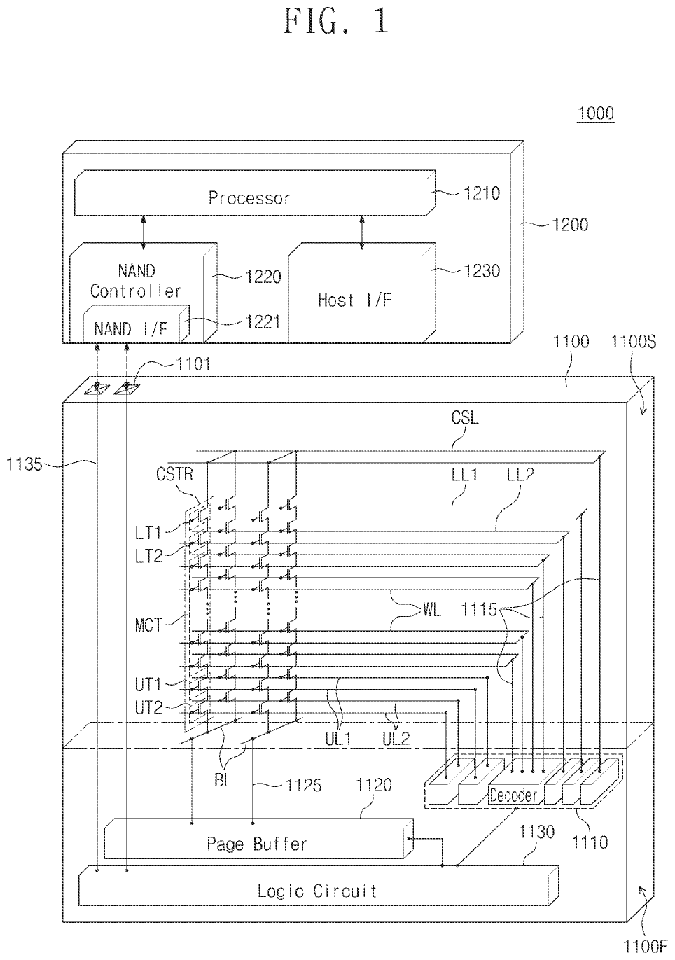

FIG. 1 is a diagram schematically illustrating an electronic system including a three-dimensional semiconductor memory device according to an embodiment of the inventive concept.

Referring to FIG. 1, an electronic system 1000 may include a three-dimensional semiconductor memory device 1100 and a controller 1200, which is electrically connected to the three-dimensional semiconductor memory device 1100. The electronic system 1000 may be a storage device including one or more three-dimensional semiconductor memory devices 1100 or an electronic device including the storage device. For example, the electronic system 1000 may be a solid state drive (SSD) device, a universal serial bus (USB), a computing system, a medical system, or a communication system, in which at least one three-dimensional semiconductor memory device 1100 is provided.

The three-dimensional semiconductor memory device 1100 may be a nonvolatile memory device (e.g., a three-dimensional NAND FLASH memory device to be described below). The three-dimensional semiconductor memory device 1100 may include a first region 1100F and a second region 1100S on the first region 1100F. However, unlike that illustrated in the drawings, the first region 1100F may be disposed beside the second region 1100S. The first region 1100F may be a peripheral circuit region, which includes a decoder circuit 1110, a page buffer 1120, and a logic circuit 1130. The second region 1100S may be a memory cell region, which includes bit lines BL, a common source line CSL, word lines WL, first lines LL1 and LL2, second lines UL1 and UL2, and memory cell strings CSTR between the bit lines BL and the common source line CSL.

In the second region 1100S, each of the memory cell strings CSTR may include first transistors LT1 and LT2 adjacent to the common source line CSL, second transistors UT1 and UT2 adjacent to the bit lines BL, and a plurality of memory cell transistors MCT disposed between the first transistors LT1 and LT2 and the second transistors UT1 and UT2. The number of the first transistors LT1 and LT2 and the number of the second transistors UT1 and UT2 may be variously changed, according to embodiments. The memory cell strings CSTR may be positioned between the common source line CSL and the first region 1100F.

For example, the second transistors UT1 and UT2 may include a string selection transistor, and the first transistors LT1 and LT2 may include a ground selection transistor. The first lines LL1 and LL2 may serve as gate electrodes of the first transistors LT1 and LT2. The word lines WL may serve as gate electrodes of the memory cell transistors MCT, and the second lines UL1 and UL2 may serve as gate electrodes of the second transistors UT1 and UT2.

For example, the first transistors LT1 and LT2 may include a first erase control transistor LT1 and a ground selection transistor LT2, which are connected in series. For example, the second transistors UT1 and UT2 may include a string selection transistor UT1 and a second erase control transistor UT2, which are connected in series. At least one of the first and second erase control transistors LT1 and UT2 may be used for an erase operation of erasing data, which are stored in the memory cell transistors MCT, using a gate-induced drain leakage (GIDL) phenomenon.

The common source line CSL, the first lines LL1 and LL2, the word lines WL, and the second lines UL1 and UL2 may be electrically connected to the decoder circuit 1110 through first interconnection lines 1115, which are extended from the first region 1100F to the second region 1100S. The bit lines BL may be electrically connected to the page buffer 1120 through second interconnection lines 1125, which are extended from the first region 1100F to the second region 1100S.

In the first region 1100F, the decoder circuit 1110 and the page buffer 1120 may be configured to perform a control operation, which is performed on at least one memory cell transistor that is selected from the memory cell transistors MCT. The decoder circuit 1110 and the page buffer 1120 may be controlled by the logic circuit 1130. The three-dimensional semiconductor memory device 1100 may communicate with the controller 1200 through an input/output pad 1101, which is electrically connected to the logic circuit 1130. The input/output pad 1101 may be electrically connected to the logic circuit 1130 through an input/output interconnection line 1135, which is extended from the first region 1100F to the second region 1100S.

The controller 1200 may include a processor 1210, a NAND controller 1220, and a host interface 1230. In an embodiment, the electronic system 1000 may include a plurality of three-dimensional semiconductor memory devices 1100, which are controlled by the controller 1200.

The processor 1210 may control overall operations of the electronic system 1000 including the controller 1200. Based on a specific firmware, the processor 1210 may execute operations of controlling the NAND controller 1220 and accessing the three-dimensional semiconductor memory device 1100. The NAND controller 1220 may include a NAND interface 1221, which is used for communication with the three-dimensional semiconductor memory device 1100. The NAND interface 1221 may be used to transmit and receive control commands to control the three-dimensional semiconductor memory device 1100, data to be written in or read from the memory cell transistors MCT of the three-dimensional semiconductor memory device 1100, and so forth. The host interface 1230 may be configured to allow for communication between the electronic system 1000 and an external host. If a control command is provided from an external host through the host interface 1230, the processor 1210 may control the three-dimensional semiconductor memory device 1100 in response to the control command.

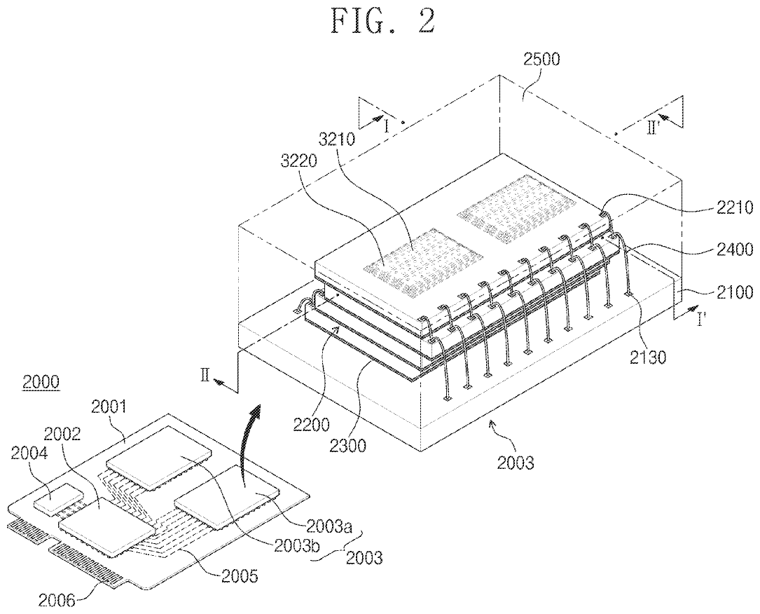

FIG. 2 is a perspective view schematically illustrating an electronic system including a three-dimensional semiconductor memory device according to an embodiment of the inventive concept.

Referring to FIG. 2, an electronic system 2000 may include a main substrate 2001 and a controller 2002, one or more semiconductor packages 2003, and a DRAM 2004, which are mounted on the main substrate 2001. The semiconductor package 2003 and the DRAM 2004 may be connected to the controller 2002 and to each other by interconnection patterns 2005, which are provided in the main substrate 2001.

The main substrate 2001 may include a connector 2006, which includes a plurality of pins coupled to an external host. In the connector 2006, the number and the arrangement of the pins may be changed depending on a communication interface between the electronic system 2000 and an external host. For example, the electronic system 2000 may communicate with the external host, in accordance with one of interfaces, such as universal serial bus (USB), peripheral component interconnect express (PCI-Express), serial advanced technology attachment (SATA), universal flash storage (UFS) M-PHY, or the like. In an embodiment, the electronic system 2000 may be driven by an electric power, which is supplied from the external host through the connector 2006. The electronic system 2000 may further include a power management integrated circuit (PMIC) that is used to separately supply the electric power, which is provided from the external host, to the controller 2002 and the semiconductor package 2003.

The controller 2002 may control a writing or reading operation on the semiconductor package 2003 and may improve an operation speed of the electronic system 2000.

The DRAM 2004 may be a buffer memory that is used to relieve technical difficulties caused by a difference in speed between the semiconductor package 2003, which serves as a data storage device, and an external host. In an embodiment, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200, which are provided on the package substrate 2100, adhesive layers 2300, which are respectively disposed in bottom surfaces of the semiconductor chips 2200, connection structures 2400, which are used to electrically connect the semiconductor chips 2200 to the package substrate 2100, and a molding layer 2500, which is provided on the package substrate 2100 to cover the semiconductor chips 2200 and the connection structures 2400.

The package substrate 2100 may be a printed circuit board including package upper pads 2130. Each of the semiconductor chips 2200 may include input/output pads 2210. Each of the input/output pads 2210 may correspond to the input/output pad 1101 of FIG. 1. Each of the semiconductor chips 2200 may include gate stacks 3210 and memory channel structures 3220. Each of the semiconductor chips 2200 may include a three-dimensional semiconductor memory device, which will be described below.

The connection structures 2400 may be, for example, bonding wires, which are used to electrically connect the input/output pads 2210 to the package upper pads 2130. That is, in each of the first and second semiconductor packages 2003a and 2003b, the semiconductor chips 2200 may be electrically connected to each other in a bonding wire manner and may be electrically connected to the package upper pads 2130 of the package substrate 2100. In an embodiment, the semiconductor chips 2200 in each of the first and second semiconductor packages 2003a and 2003b may be electrically connected to each other by through silicon vias (TSVs), not by the connection structure 2400 provided in the form of bonding wires.

Unlike that illustrated in FIG. 2, the controller 2002 and the semiconductor chips 2200 may be included in a single package. In an embodiment, the controller 2002 and the semiconductor chips 2200 may be mounted on a separate interposer substrate, not on the main substrate 2001, and may be connected to each other through interconnection lines, which are provided in the interposer substrate.

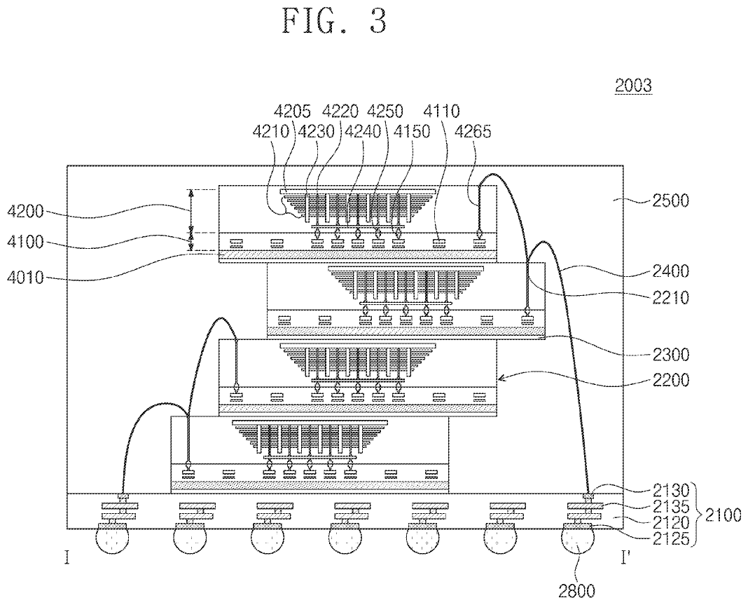

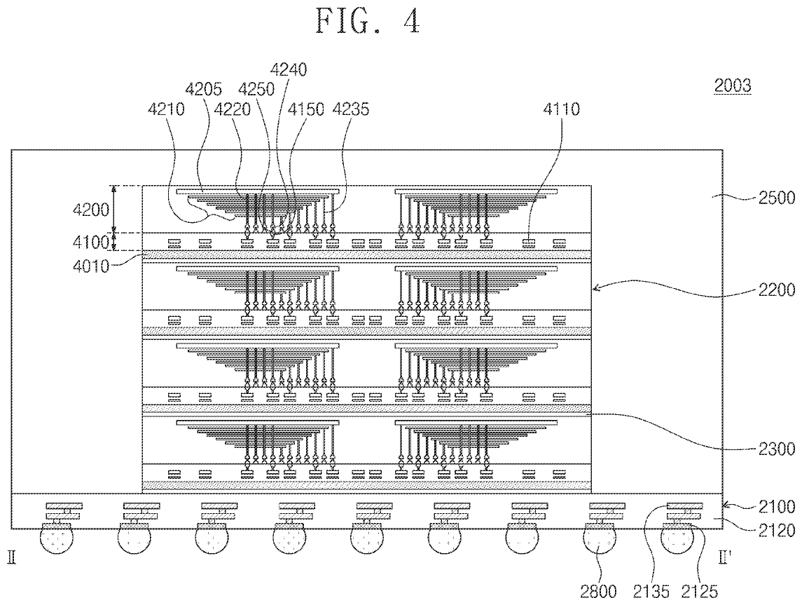

FIGS. 3 and 4 are sectional views, which are respectively taken along lines I-I′ and of FIG. 2 to illustrate a semiconductor package including a three-dimensional semiconductor memory device according to an embodiment of the inventive concept.

Referring to FIGS. 3 and 4, the semiconductor package 2003 may include the package substrate 2100, the semiconductor chips 2200 on the package substrate 2100, and the molding layer 2500 covering the package substrate 2100 and the semiconductor chips 2200.

The package substrate 2100 may include a package substrate body portion 2120, upper pads 2130, which are provided on a top surface of the package substrate body portion 2120 and are exposed to the outside of the package substrate body portion 2120 near the top surface, lower pads 2125, which are provided on a bottom surface of the package substrate body portion 2120 or are exposed to the outside of the package substrate body portion 2120 near the bottom surface, and internal lines 2135, which are provided in the package substrate body portion 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000, which is shown in FIG. 2, through conductive connecting portions 2800.

Referring to FIGS. 2 and 3, the semiconductor chips 2200 may be provided to have side surfaces, which are not aligned to each other, and other side surfaces, which are aligned to each other. The semiconductor chips 2200 may be electrically connected to each other through the connection structures 2400, which are provided in the form of bonding wires. Each of the semiconductor chips 2200 may include substantially the same elements.

Each of the semiconductor chips 2200 may include a semiconductor substrate 4010, a first structure 4100 on the semiconductor substrate 4010, and a second structure 4200 on the first structure 4100. The second structure 4200 may be connected to the first structure 4100 in a wafer bonding manner.

The first structure 4100 may include peripheral circuit interconnection lines 4110 and first bonding pads 4150. The second structure 4200 may include a common source line 4205, a gate stack 4210, which is provided between the common source line 4205 and the first structure 4100, memory channel structures 4220 and separation structures 4230, which are provided to penetrate the gate stack 4210, and second bonding pads 4250, which are electrically and respectively connected to the memory channel structures 4220 and the word lines WL (e.g., see FIG. 1) of the gate stack 4210. For example, the second bonding pads 4250 may be electrically and respectively connected to the memory channel structures 4220 and the word lines WL through bit lines 4240, which are electrically connected to the memory channel structures 4220, and gate interconnection lines 4235, which are electrically connected to the word lines WL. The first bonding pads 4150 of the first structure 4100 and the second bonding pads 4250 of the second structure 4200 may be in contact with each other and may be coupled to each other. The coupling portions between the first bonding pads 4150 and the second bonding pads 4250 may be formed of or include, for example, copper (Cu).

Each of the semiconductor chips 2200 may further include the input/output pad 2210 and an input/output interconnection line 4265 below the input/output pad 2210. The input/output interconnection line 4265 may be electrically connected to some of the second bonding pads 4250 and some of the peripheral circuit interconnection lines 4110.

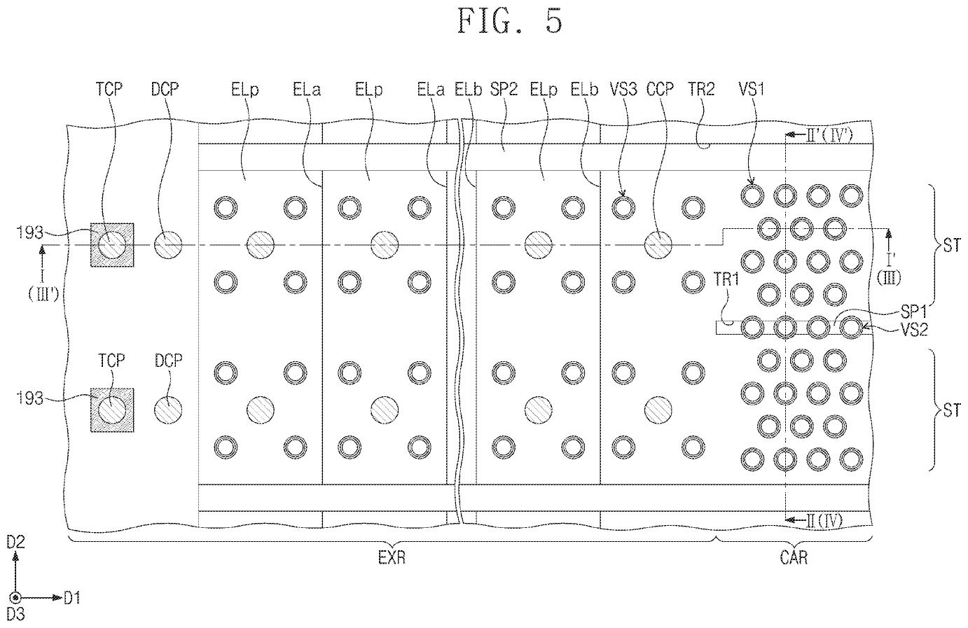

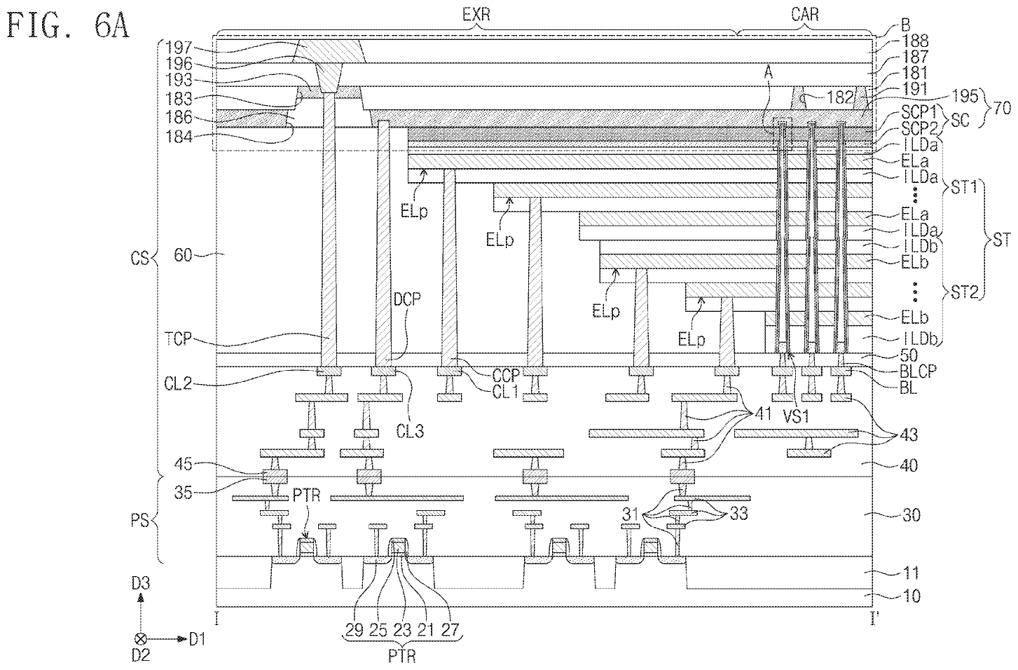

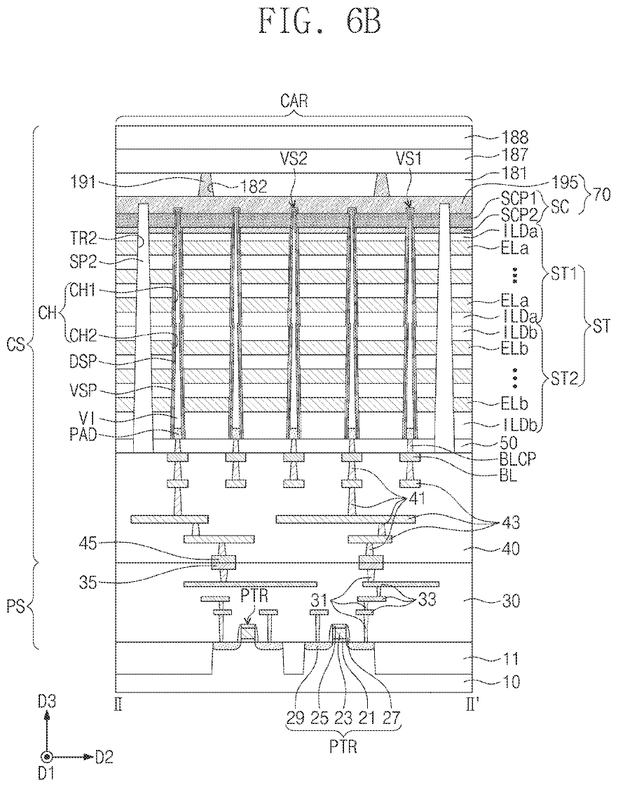

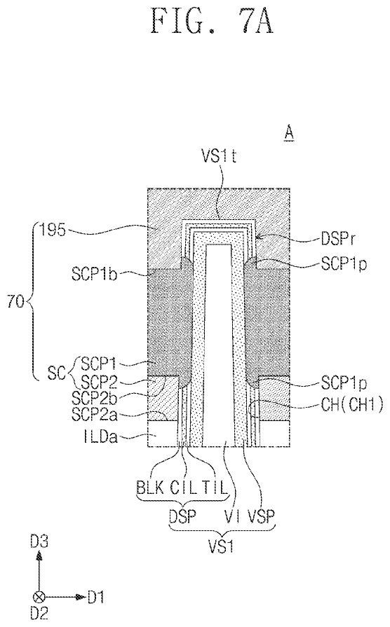

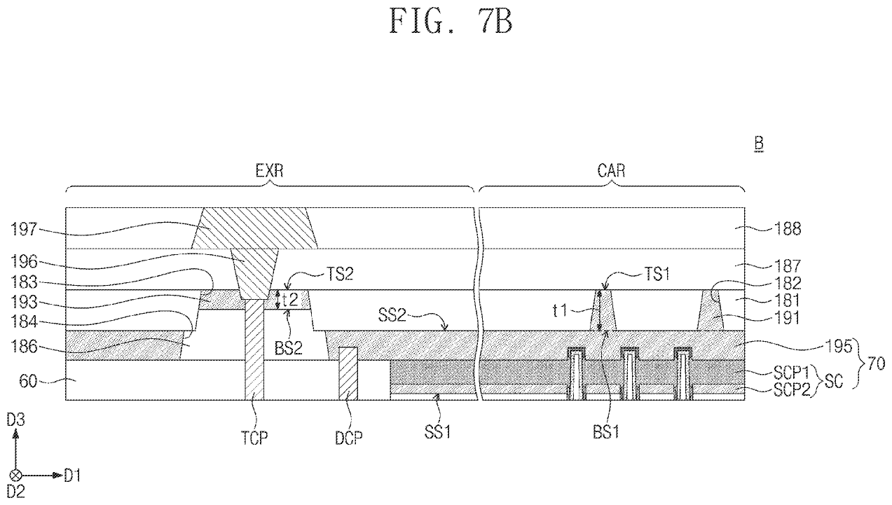

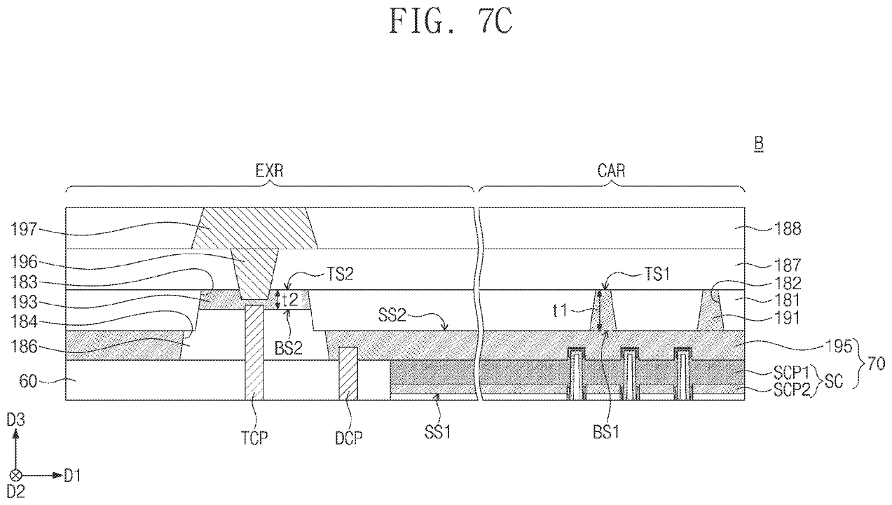

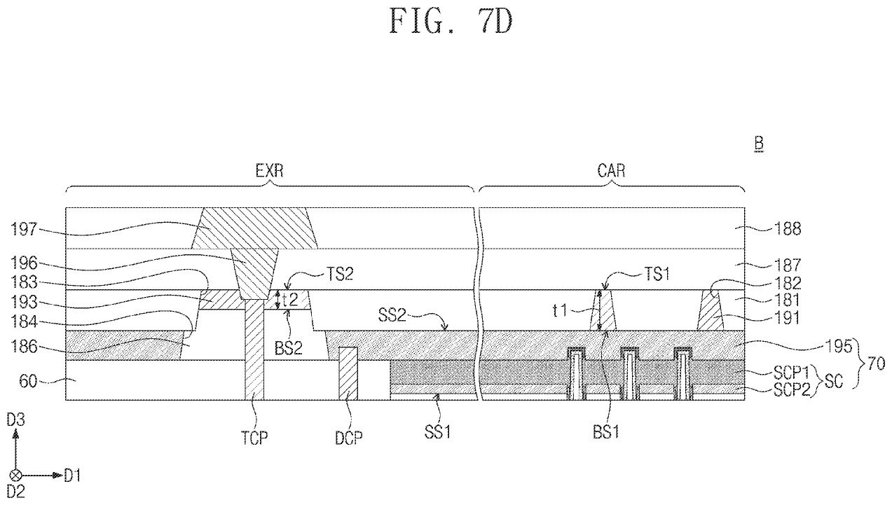

FIG. 5 is a plan view illustrating a three-dimensional semiconductor memory device according to an embodiment of the inventive concept. FIGS. 6A and 6B are sectional views, which are respectively taken along lines I-I′ and II-IF of FIG. 5 to illustrate a three-dimensional semiconductor memory device according to an embodiment of the inventive concept. FIG. 7A is an enlarged sectional view illustrating a portion ‘A’ of FIG. 6A. FIGS. 7B, 7C, and 7D are enlarged sectional views, each of which illustrates a portion (e.g., ‘B’ of FIG. 6A) of a three-dimensional semiconductor memory device according to an embodiment of the inventive concept.

Referring to FIGS. 5, 6A, and 6B, a three-dimensional semiconductor memory device according to an embodiment of the inventive concept may include a first substrate 10, a peripheral circuit structure PS on the first substrate 10, and a cell array structure CS on the peripheral circuit structure PS. The first substrate 10, the peripheral circuit structure PS, and the cell array structure CS may correspond to the semiconductor substrate 4010, the first structure 4100 on the semiconductor substrate 4010, and the second structure 4200 on the first structure 4100, respectively, described with reference to FIGS. 3 and 4.

Since the peripheral circuit structure PS is coupled to the cell array structure CS thereon, the three-dimensional semiconductor memory device may have an increased cell capacity per unit area. In addition, the peripheral circuit structure PS and the cell array structure CS may be separately fabricated and then may be coupled to each other, and in this case, it may be possible to reduce or prevent damage to peripheral transistors PTR by several thermal treatment processes. Accordingly, the electrical and reliability characteristics of the three-dimensional semiconductor memory device may be improved.

In an embodiment, the first substrate 10 may be a silicon substrate, a silicon-germanium substrate, a germanium substrate, or a structure including a single-crystalline silicon substrate and a single-crystalline epitaxial layer grown therefrom. The first substrate 10 may have a top surface that is parallel to two different directions (e.g., a first direction D1 and a second direction D2) and is perpendicular to a third direction D3. For example, the first to third directions D1, D2, and D3 may be orthogonal to each other. A device isolation layer 11 may be provided in the first substrate 10. The device isolation layer 11 may define an active region of the first substrate 10.

The peripheral circuit structure PS may be provided on the first substrate 10, and in an embodiment, the peripheral circuit structure PS may include the peripheral transistors PTR, peripheral contact plugs 31, peripheral circuit interconnection lines 33 electrically connected to the peripheral transistors PTR through the peripheral contact plugs 31, first bonding pads 35 electrically connected to the peripheral circuit interconnection lines 33, and a first interlayer insulating layer 30 enclosing them. The peripheral transistors PTR may be provided on the active region of the first substrate 10. The peripheral circuit interconnection lines 33 may correspond to the peripheral circuit interconnection lines 4110 of FIGS. 3 and 4, and the first bonding pads 35 may correspond to the first bonding pads 4150 of FIGS. 3 and 4.

In an embodiment, widths of the peripheral contact plugs 31 measured in the first or second direction D1 or D2 may increase as a distance (e.g., a distance from the first substrate 10) in the third direction D3 increases. The peripheral contact plugs 31 and the peripheral circuit interconnection lines 33 may be formed of or include at least one of conductive materials (e.g., metallic materials).

In an embodiment, the peripheral transistors PTR may constitute at least one of the decoder circuit 1110, the page buffer 1120, and the logic circuit 1130 of FIG. 1. More specifically, each of the peripheral transistors PTR may include a peripheral gate insulating layer 21, a peripheral gate electrode 23, a peripheral capping pattern 25, a peripheral gate spacer 27, and peripheral source/drain regions 29. The peripheral gate insulating layer 21 may be provided between the peripheral gate electrode 23 and the first substrate 10. The peripheral capping pattern 25 may be provided on the peripheral gate electrode 23. The peripheral gate spacer 27 may be provided to cover side surfaces of the peripheral gate insulating layer 21, the peripheral gate electrode 23, and the peripheral capping pattern 25. The peripheral source/drain regions 29 may be provided in portions of the first substrate 10, which are located at both sides of the peripheral gate electrode 23. The peripheral circuit interconnection lines 33 and the first bonding pads 35 may be electrically connected to the peripheral transistors PTR through the peripheral contact plugs 31. Each of the peripheral transistors PTR may be, for example, an NMOS transistor or a PMOS transistor.

The first interlayer insulating layer 30 may be provided on the first substrate 10. The first interlayer insulating layer 30 may cover the peripheral transistors PTR, the peripheral contact plugs 31, and the peripheral circuit interconnection lines 33, on the first substrate 10. The first interlayer insulating layer 30 may be provided to include a plurality of insulating layers or to have a multi-layered structure. In an embodiment, the first interlayer insulating layer 30 may be formed of or include at least one of silicon oxide, silicon nitride, silicon oxynitride, and/or low-k dielectric materials. The first interlayer insulating layer 30 may not cover top surfaces of the first bonding pads 35. The first interlayer insulating layer 30 may have a top surface that is substantially coplanar with the top surfaces of the first bonding pads 35.

The cell array structure CS may be provided on the peripheral circuit structure PS, and in an embodiment, the cell array structure CS may include second bonding pads 45, the bit lines BL, a stack ST, and a lower semiconductor layer 195. The cell array structure CS may include a cell array region CAR and a cell array contact region EXR. The cell array contact region EXR may be extended from the cell array region CAR in the first direction D1 (or in an opposite direction of the first direction D1).

The second bonding pads 45, the bit lines BL, the stack ST, and the lower semiconductor layer 195 may correspond to the second bonding pads 4250, the bit lines 4240, the gate stack 4210, and the common source line 4205, respectively, described with reference to FIGS. 3 and 4.

A second interlayer insulating layer 40, connection contact plugs 41, connection circuit interconnection lines 43, and the second bonding pads 45 may be provided on the first interlayer insulating layer 30. Here, the second bonding pads 45 may be provided to be in contact with the first bonding pads 35 of the peripheral circuit structure PS, the connection circuit interconnection lines 43 may be electrically connected to the second bonding pads 45 through the connection contact plugs 41, and the second interlayer insulating layer 40 may be provided to enclose the connection contact plugs 41, the connection circuit interconnection lines 43, and the second bonding pads 45.

The second interlayer insulating layer 40 may have a multi-layered structure including a plurality of insulating layers. In an embodiment, the second interlayer insulating layer 40 may be formed of or include at least one of silicon oxide, silicon nitride, silicon oxynitride, and/or low-k dielectric materials.

In an embodiment, widths of the connection contact plugs 41 measured in the first or second direction D1 or D2 may decrease as a distance (e.g., a distance from the first substrate 10) in the third direction D3 increases. The connection contact plugs 41 and the connection circuit interconnection lines 43 may be formed of or include at least one of conductive materials (e.g., metallic materials).

The second interlayer insulating layer 40 may not cover bottom surfaces of the second bonding pads 45. A bottom surface of the second interlayer insulating layer 40 may be substantially coplanar with the bottom surfaces of the second bonding pads 45. The bottom surface of each of the second bonding pads 45 may be in direct contact with the top surface of a corresponding one of the first bonding pads 35. The first and second bonding pads 35 and 45 may be formed of or include at least one of metallic materials (e.g., copper (Cu), tungsten (W), aluminum (Al), nickel (Ni), or tin (Sn)). For example, the first and second bonding pads 35 and 45 may be formed of or include copper (Cu). The first and second bonding pads 35 and 45 may be connected to each other without any interface therebetween and may form a single object. The side surfaces of the first and second bonding pads 35 and 45 are illustrated to be aligned to each other, but the inventive concept is not limited to this example. For example, the side surfaces of the first and second bonding pads 35 and 45 may be spaced apart from each other, when viewed in a plan view.

The bit lines BL and first to third conductive lines CL1, CL2, and CL3, which are in contact with the connection contact plugs 41, may be provided in an upper portion of the second interlayer insulating layer 40. In an embodiment, the bit lines BL and the first to third conductive lines CL1, CL2, and CL3 may be extended in the second direction D2 and may be spaced apart from each other in the first direction D1. The bit lines BL and the first to third conductive lines CL1, CL2, and CL3 may be formed of or include at least one of conductive materials (e.g., metallic materials).

A third interlayer insulating layer 50 may be provided on the second interlayer insulating layer 40. A fourth interlayer insulating layer 60 and the stack ST may be provided on the third interlayer insulating layer 50, and here, the stack ST may be enclosed by the fourth interlayer insulating layer 60. The third and fourth interlayer insulating layers 50 and 60 may be a multi-layered structure including a plurality of insulating layers. In an embodiment, the third and fourth interlayer insulating layers 50 and 60 may be formed of or include at least one of silicon oxide, silicon nitride, silicon oxynitride, and/or low-k dielectric materials.

Bit line contact plugs BLCP may be provided in the third interlayer insulating layer 50. The bit line contact plugs BLCP may be extended in the third direction D3 to connect the bit lines BL to first vertical channel structures VS1, which will be described below.

Cell contact plugs CCP, a source contact plug DCP, and a penetration contact plug TCP may be provided to penetrate the third interlayer insulating layer 50 and the fourth interlayer insulating layer 60. The cell contact plugs CCP may be extended in the third direction D3 to connect the first conductive lines CL1 to gate electrodes ELa and ELb of the stack ST, which will be described below. Each of the cell contact plugs CCP may be provided to penetrate one of interlayer dielectric layers ILDa and ILDb of the stack ST, which will be described below. The penetration contact plug TCP may be extended in the third direction D3 to connect the second conductive line CL2 to a back-side conductive pattern 197, which will be described below. The source contact plug DCP may be extended in the third direction D3 to connect the lower semiconductor layer 195 to the third conductive line CL3.

The bit line contact plugs BLCP, the cell contact plugs CCP, and the penetration contact plug TCP may be spaced apart from each other in the first direction D1. Widths of the bit line contact plugs BLCP, the cell contact plugs CCP, the source contact plug DCP, and the penetration contact plug TCP, which are measured in the first and/or second directions D1 and/or D2, may decrease with increasing distance (e.g., distance from the first substrate 10) in the third direction D3. The bit line contact plugs BLCP, the cell contact plugs CCP, the source contact plug DCP, and the penetration contact plug TCP may be formed of or include at least one of metallic materials (e.g., tungsten).

The stack ST may be provided on the third interlayer insulating layer 50. The stack ST may be enclosed by the fourth interlayer insulating layer 60. A bottom surface of the stack ST (i.e., a surface in contact with the third interlayer insulating layer 50) may be substantially coplanar with a bottom surface of the fourth interlayer insulating layer 60.

In an embodiment, a plurality of the stacks ST may be provided. The stacks ST may be extended in the first direction D1 and may be spaced apart from each other in the second direction D2, when viewed in the plan view of FIG. 5. Hereinafter, just one stack ST will be described, for brevity's sake, but the others of the stacks ST may also have substantially the same features as described below.

The stack ST may include a first stack ST1 and a second stack ST2. The first stack ST1 may include first interlayer dielectric layers ILDa and first gate electrodes Ela, which are alternatively stacked, and the second stack ST2 may include second interlayer dielectric layers ILDb and second gate electrodes ELb, which are alternatively stacked.

The second stack ST2 may be provided between the first stack ST1 and the first substrate 10. More specifically, the second stack ST2 may be provided on a bottom surface of the bottommost one of the first interlayer dielectric layers ILDa of the first stack ST1. The topmost one of the second interlayer dielectric layers ILDb of the second stack ST2 may be in contact with the bottommost one of the first interlayer dielectric layers ILDa of the first stack ST1, but the inventive concept is not limited to this example. For example, a single insulating layer may be provided between the topmost one of the second gate electrodes ELb of the second stack ST2 and the first gate electrodes ELa of the first stack ST1.

The first and second gate electrodes ELa and ELb may be formed of or include at least one of, for example, doped semiconductor materials (e.g., doped silicon and so forth), metallic materials (e.g., tungsten, copper, aluminum, and so forth), conductive metal nitrides (e.g., titanium nitride, tantalum nitride, and so forth), or transition metals (e.g., titanium, tantalum, and so forth). The first and second interlayer dielectric layers ILDa and ILDb may be formed of or include at least one of silicon oxide, silicon nitride, silicon oxynitride, and/or low-k dielectric materials. For example, the first and second interlayer dielectric layers ILDa and ILDb may be formed of or include high density plasma (HDP) oxide or tetraethyl orthosilicate (TEOS).

On the cell array contact region EXR, a thickness of each of the first and second stacks ST1 and ST2 in the third direction D3 may decrease with increasing distance from the outermost one of the first vertical channel structures VS1, which will be described below. That is, each of the first and second stacks ST1 and ST2 may have a staircase structure in the first direction D1.

More specifically, lengths of the first gate electrodes ELa of the first stack ST1 and the second gate electrodes ELb of the second stack ST2 in the first direction D1 may increase with increasing distance from the first substrate 10. Side surfaces of the first and second gate electrodes ELa and ELb may be spaced apart from each other by a specific distance in the first direction D1, when viewed in the plan view of FIG. 5. The lowermost one of the second gate electrodes ELb of the second stack ST2 may have the smallest length in the first direction D1, and the uppermost one of the first gate electrodes ELa of the first stack ST1 may have the largest length in the first direction D1.

The first and second gate electrodes ELa and ELb may include pad portions ELp, which are provided on the cell array contact region EXR. The pad portions ELp may be disposed at positions that are different from each other in horizontal and vertical directions. The pad portions ELp may form a staircase structure in the first direction D1. Each of the cell contact plugs CCP may penetrate a corresponding one of the first and second interlayer dielectric layers ILDa and ILDb and may be in contact with the pad portion ELp of a corresponding one of the first and second gate electrodes ELa and ELb.

Each of the first and second interlayer dielectric layers ILDa and ILDb may be provided between a corresponding pair of the first and second gate electrodes ELa and ELb and may have a side surface that is aligned to a side surface of a corresponding one of the first and second gate electrodes ELa and ELb in contact therewith. That is, similar to the first and second gate electrodes ELa and ELb, lengths of the first and second interlayer dielectric layers ILDa and ILDb in the first direction D1 may increase with increasing distance from the first substrate 10. In an embodiment, the bottommost one of the second interlayer dielectric layers ILDb may have the largest thickness in the third direction D3, and the topmost one of the first interlayer dielectric layers ILDa may have the smallest thickness in the third direction D3. However, the inventive concept is not limited to this example.

Vertical channel holes CH may be formed on the cell array region CAR to penetrate the stack ST in the third direction D3, and first and second vertical channel structures VS1 and VS2 may be provided in the vertical channel holes CH. The first vertical channel structures VS1 may correspond to the memory channel structures 4220 of FIGS. 3 and 4.

The vertical channel holes CH may also be formed on the cell array contact region EXR to penetrate at least a portion of the stack ST and the fourth insulating layer 60 in the third direction D3, and third vertical channel structures VS3 may be provided in the vertical channel holes CH, which are formed on the cell array contact region EXR.

The vertical channel holes CH may include first vertical channel holes CH1 and second vertical channel holes CH2, which are connected to the first vertical channel holes CH1. Widths of the first and second vertical channel holes CH1 and CH2 measured in the first or second direction D1 or D2 may decrease with increasing distance from the first substrate 10. The first and second vertical channel holes CH1 and CH2 may have different diameters from each other near a boundary region, where the first and second vertical channel holes CH1 and CH2 are connected to each other. In detail, an upper diameter (e.g., a diameter of an upper portion) of each of the second vertical channel holes CH2 may be smaller than a lower diameter (e.g., a diameter of a lower portion) of each of the first vertical channel holes CH1. The first and second vertical channel holes CH1 and CH2 may form a stepwise structure near the boundary region. However, the inventive concept is not limited to this example, and in an embodiment, the first to third vertical channel structures VS1, VS2, and VS3 may be provided in three or more vertical channel holes CH, which are provided to form stepwise structures at two or more different levels, or may be provided in the vertical channel holes CH whose side surfaces are substantially flat without such a stepwise structure.

As shown in FIGS. 6B and 7A, each of the first to third vertical channel structures VS1, VS2, and VS3 may include a conductive pad PAD, which is adjacent to the third interlayer insulating layer 50, a data storage pattern DSP, which is provided to conformally cover an inner side surface of each of the first and second vertical channel holes CH1 and CH2, a vertical semiconductor pattern VSP, which is provided to conformally cover a side surface of the data storage pattern DSP, and a gap-fill insulating pattern VI, which is provided to fill an internal space of each of the first and second vertical channel holes CH1 and CH2 enclosed by the vertical semiconductor pattern VSP and the conductive pad PAD. The vertical semiconductor pattern VSP may be enclosed by the data storage pattern DSP. In an embodiment, each of the first to third vertical channel structures VS1, VS2, and VS3 may have a circular, elliptical, or bar-shaped bottom surface.

The vertical semiconductor pattern VSP may be provided between the data storage pattern DSP and the gap-fill insulating pattern VI and between the data storage pattern DSP and the conductive pad PAD. The vertical semiconductor pattern VSP may have a top-closed pipe or macaroni structure. The data storage pattern DSP may have a top-opened pipe or macaroni structure. The vertical semiconductor pattern VSP may be formed of or include at least one of doped semiconductor materials or undoped or intrinsic semiconductor materials and may have a poly-crystalline structure. In an embodiment, the conductive pad PAD may be formed of or include at least one of doped semiconductor materials or conductive materials.

When viewed in the plan view of FIG. 5, a first trench TR1 and a second trench TR2 may be provided to extend in the first direction D1 and to cross the stack ST. The first trench TR1 may be provided in the cell array region CAR, and the second trench TR2 may be extended from the cell array region CAR toward the cell array contact region EXR. A width of each of the first and second trenches TR1 and TR2 in the first or second direction D1 or D2 may decrease with increasing distance from the first substrate 10.

A first separation pattern SP1 and a second separation pattern SP2 may be provided to fill the first trench TR1 and the second trench TR2, respectively. The first and second separation patterns SP1 and SP2 may correspond to the separation structures 4230 of FIGS. 3 and 4. A length of the second separation pattern SP2 in the first direction D1 may be larger than a length of the first separation pattern SP1 in the first direction D1. Side surfaces of the first and second separation patterns SP1 and SP2 may be in contact with at least a portion of the first and second gate electrodes ELa and ELb and the first and second interlayer dielectric layers ILDa and ILDb of the stack ST. In an embodiment, the first and second separation patterns SP1 and SP2 may be formed of or include at least one of oxide materials (e.g., silicon oxide).

A bottom surface of the second separation pattern SP2 may be substantially coplanar with the bottom surface of the third interlayer insulating layer 50 (i.e., the top surface of the second interlayer insulating layer 40) and the top surfaces of the bit lines BL and the first and second conductive lines CL1 and CL2. A top surface of the second separation pattern SP2 may be located at a level that is higher than the top surfaces of the first to third vertical channel structures VS1, VS2, and VS3, but the inventive concept is not limited to this example.

In the case where a plurality of the stacks ST are provided, the first separation pattern SP1 or the second separation pattern SP2 may be provided between the stacks ST that are arranged in the second direction D2. For example, the stacks ST may be spaced apart from each other in the second direction D2 with the first or second separation pattern SP1 or SP2 interposed therebetween.

A second substrate 70 may be provided on the stack ST. That is, the stack ST may be provided on a first surface (e.g., SS1 of FIG. 7B) of the second substrate 70. The second substrate 70 may be connected to a lower portion of each of the first and second vertical channel structures VS1 and VS2. The second substrate 70 may include the lower semiconductor layer 195, which is provided on the stack ST, and a source structure SC, which is provided between the stack ST and the lower semiconductor layer 195. The lower semiconductor layer 195 and the source structure SC may be extended in the first and second directions D1 and D2 to be parallel to a top surface of the first substrate 10 (or a top surface of the stack ST). The lower semiconductor layer 195 may be a plate-shape pattern that is extended parallel to the top surface of the first substrate 10.

In an embodiment, the lower semiconductor layer 195 may be formed of or include a doped polycrystalline semiconductor material or a doped single-crystalline semiconductor material. The source structure SC may include a first source conductive pattern SCP1 on the stack ST and a second source conductive pattern SCP2 between the stack ST and the first source conductive pattern SCP1. The second source conductive pattern SCP2 may be provided between the first source conductive pattern SCP1 and the topmost one of the first interlayer dielectric layers ILDa of the first stack ST1. The second source conductive pattern SCP2 may be in direct contact with the first source conductive pattern SCP1. A thickness of the first source conductive pattern SCP1 in the third direction D3 may be larger than a thickness of the second source conductive pattern SCP2 in the third direction D3. The source structure SC may be formed of or include at least one of doped semiconductor materials. The source structure SC may be formed of or include a doped semiconductor material, which is doped to have the same conductivity type as the lower semiconductor layer 195. For example, an impurity concentration of the first source conductive pattern SCP1 may be higher than an impurity concentration of the second source conductive pattern SCP2.

A fifth interlayer insulating layer 181, a sixth interlayer insulating layer 187, and a seventh interlayer insulating layer 188 may be sequentially provided on a second surface SS2 (e.g., see FIG. 7B) of the second substrate 70. The second surface may be a surface that is opposite to the first surface. A back-side via 191 and a contact pad 193 may be provided in the fifth interlayer insulating layer 181. A penetration via 196, which is connected to the penetration contact plug TCP, may be provided in the sixth interlayer insulating layer 187. A back-side conductive pattern 197, which is connected to the penetration via 196, may be provided in the seventh interlayer insulating layer 188.

FIG. 7A is an enlarged sectional view illustrating a portion of a three-dimensional semiconductor memory device according to an embodiment of the inventive concept and corresponding to a portion ‘A’ of FIG. 6A.

The second substrate 70, which includes the lower semiconductor layer 195 and the source structure SC, and one of the first vertical channel structures VS1, which includes the data storage pattern DSP, the vertical semiconductor pattern VSP, the gap-fill insulating pattern VI, and a lower data storage pattern DSPr, will be described in more detail with reference to FIGS. 6A and 7A. Hereinafter, one of the vertical channel holes CH and one of the first vertical channel structures VS1 will be described, for brevity's sake, but the others may have substantially the same features as described below.

A top surface VS1t of the first vertical channel structure VS1 may be in contact with the lower semiconductor layer 195. The top surface VS1t of the first vertical channel structure VS1 may correspond to a top surface of the lower data storage pattern DSPr. The top surface VS1t of the first vertical channel structure VS1 may be located at a level higher than a top surface SCP1b of the first source conductive pattern SCP1.

The data storage pattern DSP may include a blocking insulating layer BLK, a charge storing layer CIL, and a tunneling insulating layer TIL, which are sequentially stacked on a side surface of the vertical channel hole CH. The blocking insulating layer BLK may be adjacent to the stack ST or the source structure SC, and the tunneling insulating layer TIL may be adjacent to the vertical semiconductor pattern VSP. The charge storing layer CIL may be interposed between the blocking insulating layer BLK and the tunneling insulating layer TIL. The blocking insulating layer BLK, the charge storing layer CIL, and the tunneling insulating layer TIL may be extended from a region between the stack ST and the vertical semiconductor pattern VSP in the third direction D3. In an embodiment, the Fowler-Nordheim (FN) tunneling phenomenon, which is caused by a voltage difference between the vertical semiconductor pattern VSP and the first and second gate electrodes ELa and ELb, may be used to store or change data in the data storage pattern DSP. In an embodiment, the blocking insulating layer BLK and the tunneling insulating layer TIL may be formed of or include silicon oxide, and the charge storing layer CIL may be formed of or include silicon nitride or silicon oxynitride.

The first source conductive pattern SCP1 of the source structure SC may be in contact with the vertical semiconductor pattern VSP, and the second source conductive pattern SCP2 may be spaced apart from the vertical semiconductor pattern VSP with the data storage pattern DSP interposed therebetween. The first source conductive pattern SCP1 may be spaced apart from the gap-fill insulating pattern VI with the vertical semiconductor pattern VSP interposed therebetween.

More specifically, the first source conductive pattern SCP1 may include protruding portions SCP1p, which are located at a level that is lower than a top surface SCP2b of the second source conductive pattern SCP2 or is higher than the top surface SCP1b of the first source conductive pattern SCP1. However, the protruding portions SCP1p may be located at a level higher than a bottom surface SCP2a of the second source conductive pattern SCP2. In an embodiment, each of the protruding portions SCP1p, which are in contact with the data storage pattern DSP or the lower data storage pattern DSPr, may have a curved surface.

Hereinafter, the back-side via 191, the contact pad 193, and a structure adjacent thereto will be described in more detail with reference to FIGS. 7B, 7C, and 7D.

Referring to FIGS. 6A, 7B, 7C, and 7D, a plurality of the back-side vias 191 may be provided, and in an embodiment, the back-side vias 191 may protrude from a second surface SS2 of the second substrate 70 in the third direction D3. The back-side via 191 is illustrated to be provided on the cell array region CAR, but in an embodiment, the back-side via 191 may be provided on the cell array contact region EXR. The back-side via 191 may be used to reduce or prevent the occurrence of an arcing phenomenon when an etching process is performed to form the vertical channel holes CH or penetration holes for contact plugs, as will be described with reference to a fabrication method below. The back-side via 191 may not be electrically connected to any conductive or semiconductor layer other than the lower semiconductor layer 195.

The contact pad 193 may be disposed at the same level as the back-side via 191. For example, both of the contact pad 193 and the back-side via 191 may be disposed in the fifth interlayer insulating layer 181. In the present specification, if two elements are disposed or located at the same level, at least a portion of one of them may be horizontally overlapped with another. In more detail, the back-side via 191 may be provided to fill a first penetration hole 182 in the fifth interlayer insulating layer 181, and the contact pad 193 may be provided to fill a second penetration hole 183 in the fifth interlayer insulating layer 181. The contact pads 193, which are respectively connected to the penetration contact plugs TCP, may be spaced apart from each other, as shown in FIG. 5. The contact pad 193 may be used to reduce or prevent the occurrence of an arcing phenomenon in a process of forming a penetration hole for the penetration contact plug TCP, and furthermore, it may be used as an etch stop layer in the process of forming the penetration hole.

A width of a bottom surface BS1 of the back-side via 191 may be larger than a width of a top surface TS1. A width of a bottom surface BS2 of the contact pad 193 may be larger than a width of a top surface TS2. The top surface TS1 of the back-side via 191 and the top surface TS2 of the contact pad 193 may be located at substantially the same height, when measured from the second surface SS2 of the second substrate 70. The bottom surface BS2 of the contact pad 193 may be higher than the bottom surface BS1 of the back-side via 191. A thickness t2 of the contact pad 193 may be smaller than a thickness t1 of the back-side via 191. When measured in the first direction D1, a width (e.g., a widest width) of the contact pad 193 may be larger than a width (e.g., a widest width) of the back-side via 191. Similarly, when measured in the second direction D2, a width of the contact pad 193 may be larger than a width of the back-side via 191.

A capping insulating pattern 186 may be provided to fill a third penetration hole 184, which is formed to penetrate the second substrate 70 (in particular, the lower semiconductor layer 195). The capping insulating pattern 186 may be extended into the second penetration hole 183 to cover the bottom surface BS2 of the contact pad 193.

An interface or boundary between the penetration contact plug TCP and the penetration via 196 may be located in the contact pad 193. In other words, the penetration via 196 may penetrate the sixth interlayer insulating layer 187 and may be inserted into an upper portion of the contact pad 193, and thus, a bottom surface of the penetration via 196 may be placed in the contact pad 193. For example, as shown in FIGS. 7B and 7D, the penetration contact plug TCP and the penetration via 196 may be in contact with each other, in the contact pad 193. Alternatively, as shown in FIG. 7C, the penetration contact plug TCP and the penetration via 196 may be spaced apart from each other with the contact pad 193 interposed therebetween. The penetration via 196 may be provided to have a top surface whose width is larger than that of a bottom surface thereof. The top surface of the penetration via 196 may be higher than the top surface TS1 of the back-side via 191 and the top surface TS2 of the contact pad 193. The penetration contact plug TCP may penetrate the second substrate 70 through the third penetration hole 184 and may be connected to the contact pad 193.

The back-side conductive pattern 197 may be provided on the penetration via 196. For the back-side conductive pattern 197, a width of a bottom surface may be smaller than a width of a top surface. The back-side conductive pattern 197 may be electrically connected to the second conductive line CL2 through the penetration via 196 and the penetration contact plug TCP, and moreover, it may be electrically connected to at least one of the peripheral transistors PTR of the peripheral circuit structure PS. The back-side conductive pattern 197 may correspond to one of the input/output pad 1101 of FIG. 1 or the input/output pads 2210 of FIGS. 3 and 4. However, in an embodiment, the back-side conductive pattern 197 may be one of back-side metal lines. The back-side conductive pattern 197 may be formed of or include a material that is different from the penetration via 196 and the penetration contact plug TCP. In an embodiment, the back-side conductive pattern 197 may be formed of or include aluminum, and the penetration via 196 and the penetration contact plug TCP may be formed of or include at least one of tungsten, titanium, or tantalum.

The back-side via 191 and the contact pad 193 may be formed of or include the same material. As an example, the back-side via 191 and the contact pad 193 may be portions of a layer that is formed of the same material. In an embodiment, the back-side via 191 and the contact pad 193 may be formed of or include at least one of a semiconductor material, which is doped with impurities of a first conductivity type (e.g., n-type), or a conductive material (e.g., a metallic material).

Referring to FIGS. 7B and 7C, the back-side via 191 and the contact pad 193 may be formed of the same material as the lower semiconductor layer 195. Thus, there may be no interface between the back-side via 191 and the lower semiconductor layer 195. In some embodiments, the interface between the back-side via 191 and the lower semiconductor layer 195 may not be visible. In an embodiment, each of the back-side via 191, the contact pad 193, and the lower semiconductor layer 195 may include a poly silicon layer. Referring to FIG. 7D, the back-side via 191 and the contact pad 193 may be formed of a material that is different from the lower semiconductor layer 195. In this case, there may be an interface between the back-side via 191 and the lower semiconductor layer 195. In an embodiment, the back-side via 191 and the contact pad 193 may be formed of or include at least one of metallic materials (e.g., tungsten, titanium, tantalum, and conductive metal nitrides thereof). By contrast, the lower semiconductor layer 195 may be formed of or include poly silicon. A metal silicide layer may be additionally provided between the back-side via 191 and the lower semiconductor layer 195, but the inventive concept is not limited to this example. For example, the back-side via 191 and the contact pad 193 may each include tungsten, titanium and/or tantalum. As used herein the term “and/or” includes any and all combinations of one or more of the associated listed items.

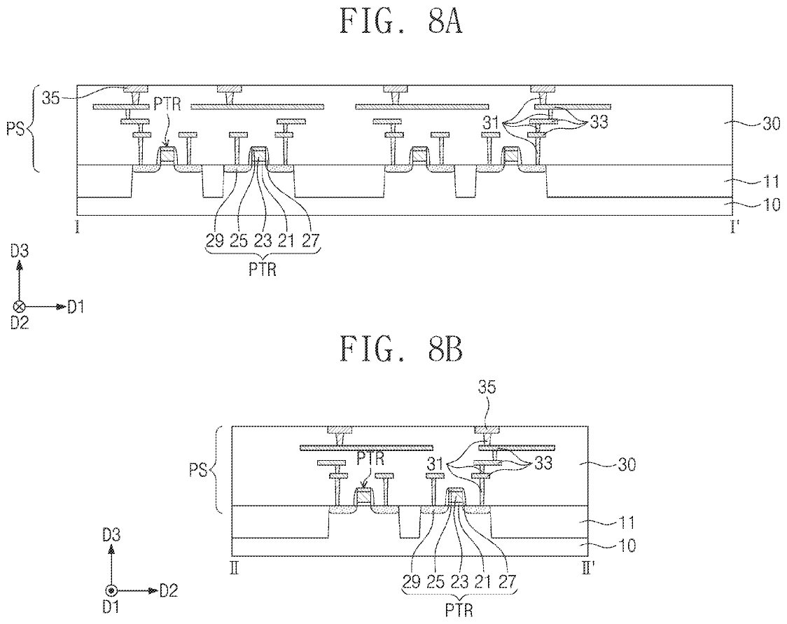

FIGS. 8A, 14A, and 15A are sectional views, which are taken along the line I-I′ of FIG. 5 to illustrate a method of fabricating a three-dimensional semiconductor memory device according to an embodiment of the inventive concept. FIGS. 8B, 14B, and 15B are sectional views, which are taken along the line II-II′ of FIG. 5 to illustrate a method of fabricating a three-dimensional semiconductor memory device according to an embodiment of the inventive concept.

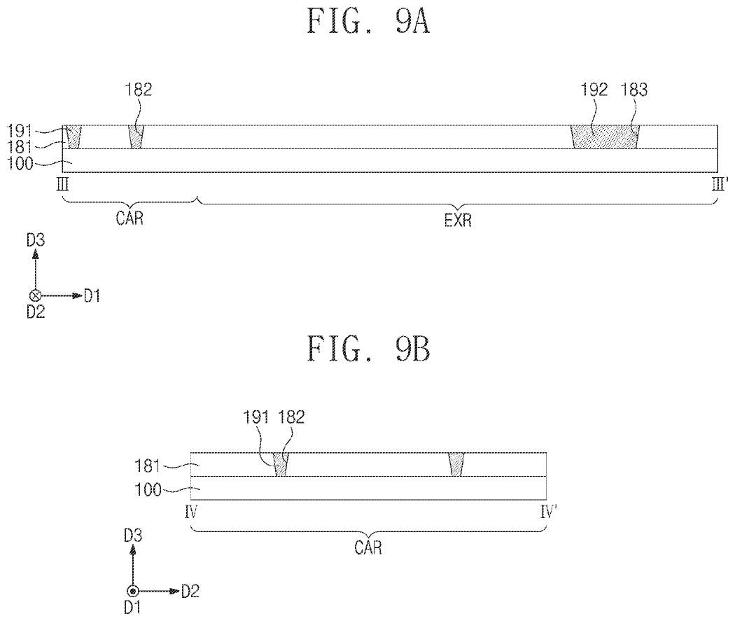

FIGS. 9A, 10A, 11A, 12A and 13A are sectional views, which are taken along a line III-III′ of FIG. 5 to illustrate a method of fabricating a three-dimensional semiconductor memory device according to an embodiment of the inventive concept. FIGS. 9B, 10B, 11B, 12B and 13B are sectional views, which are taken along a line IV-IV′ of FIG. 5 to illustrate a method of fabricating a three-dimensional semiconductor memory device according to an embodiment of the inventive concept.

Referring to FIGS. 8A and 8B, the peripheral circuit structure PS may be formed on the first substrate 10. The formation of the peripheral circuit structure PS may include forming the device isolation layer 11 in the first substrate 10 to define an active region, forming the peripheral transistors PTR on the active region of the first substrate 10, and forming the peripheral contact plugs 31, the peripheral circuit interconnection lines 33, the first bonding pads 35, which are electrically connected to the peripheral transistors PTR, and the first interlayer insulating layer 30 covering them.

The first bonding pads 35 may be formed to have top surfaces that are substantially coplanar with a top surface of the first interlayer insulating layer 30. In the following description, the expression of “two elements are coplanar with each other” may mean that a planarization process may be performed on the elements. The planarization process may be performed using, for example, a chemical mechanical polishing (CMP) process or an etch-back process.

Referring to FIGS. 9A and 9B, the fifth interlayer insulating layer 181 may be formed on a carrier substrate 100. The fifth interlayer insulating layer 181 may be formed of or include silicon oxide. The first penetration hole 182 and the second penetration hole 183 may be formed to penetrate the fifth interlayer insulating layer 181 and to expose the carrier substrate 100. In an embodiment, a plurality of the first penetration holes 182 may be formed on the cell array region CAR and/or the cell array contact region EXR. In an embodiment, one or more second penetration holes 183 may be formed on the cell array contact region EXR. Each of the first and second penetration holes 182 and 183 may be formed to have a bottom portion that is narrower than its top portion, due to an etching property in an etching process to form them.

The back-side via 191 may be formed to fill the first penetration hole 182, and a preliminary contact pad 192 may be formed to fill the second penetration hole 183. The back-side via 191 and the preliminary contact pad 192 may be in contact with the carrier substrate 100. The back-side via 191 and the preliminary contact pad 192 may be formed of the same material and through the same deposition process. In an embodiment, the back-side via 191 and the preliminary contact pad 192 may be formed of poly silicon or tungsten, as described with reference to FIGS. 7B to 7D. As an example, the back-side via 191 and the preliminary contact pad 192 may be formed by depositing a doped semiconductor material (e.g., doped poly silicon) of a first conductivity type (e.g., n-type).

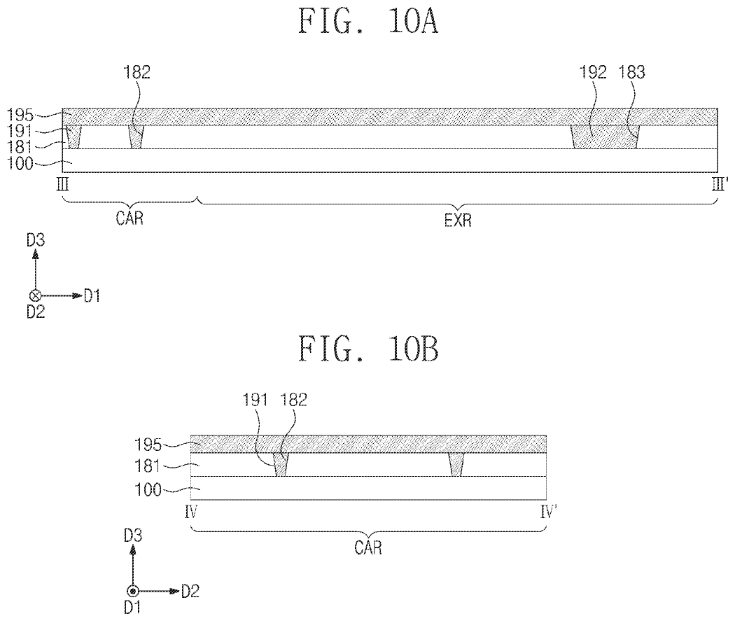

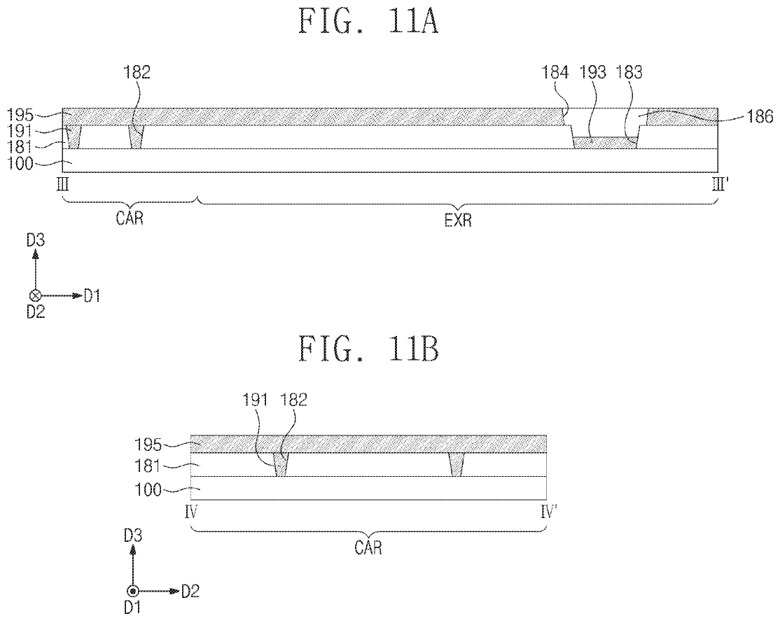

Referring to FIGS. 10A and 10B, the lower semiconductor layer 195 may be formed to cover the back-side via 191 and the preliminary contact pad 192. The lower semiconductor layer 195 may be formed of poly silicon. In the case where the back-side via 191 and the preliminary contact pad 192 are also formed of poly silicon, the back-side via 191, the preliminary contact pad 192, and the lower semiconductor layer 195 may be formed through successive deposition processes. Alternatively, if the back-side via 191 and the preliminary contact pad 192 are formed of a different material (e.g., tungsten) from the lower semiconductor layer 195, a planarization process may be performed before the formation of the lower semiconductor layer 195.

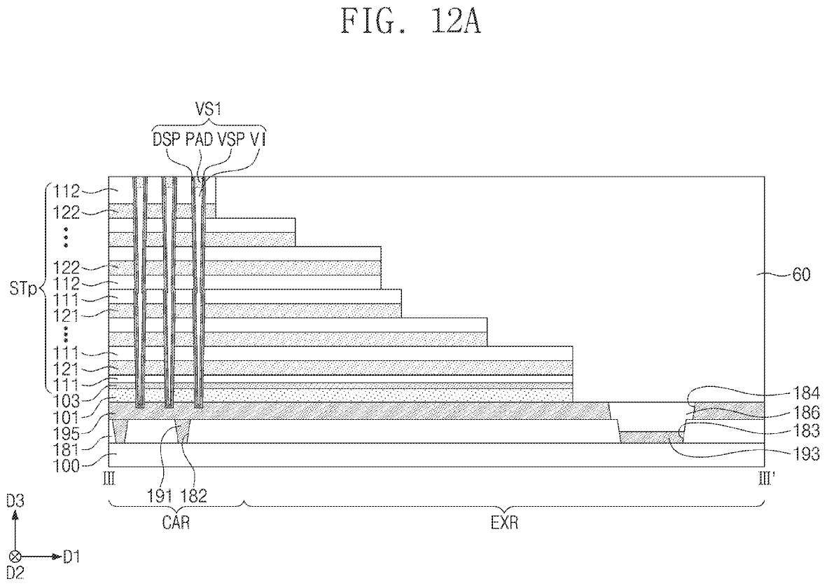

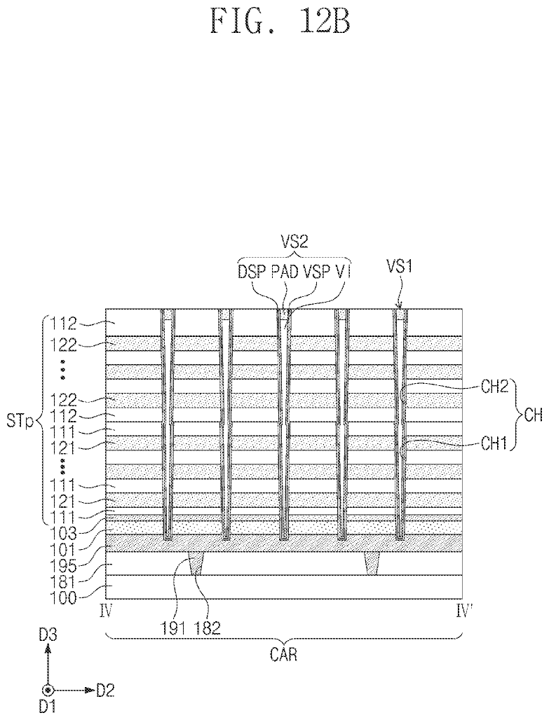

Referring to FIGS. 11A and 11B, the third penetration hole 184 may be formed to penetrate the lower semiconductor layer 195. The third penetration hole 184 may be formed by an etching process using a mask pattern. An upper portion of the second penetration hole 183 may be exposed to the process of forming the third penetration hole 184, and in this case, an upper portion of the preliminary contact pad 192 may be recessed by the etching process, which is performed to form the third penetration hole 184, to form the contact pad 193. In an embodiment, about ⅓ to ⅔ of the thickness of the preliminary contact pad 192 may be removed, during the process of forming the third penetration hole 184. As a result, the contact pad 193 may be separated from the lower semiconductor layer 195. Thereafter, the capping insulating pattern 186 may be formed to fill the third penetration hole 184 and to cover a top surface of the contact pad 193. In an embodiment, the capping insulating pattern 186 may be formed by forming a silicon oxide layer to fill the third penetration hole 184 and performing a planarization process on the silicon oxide layer.

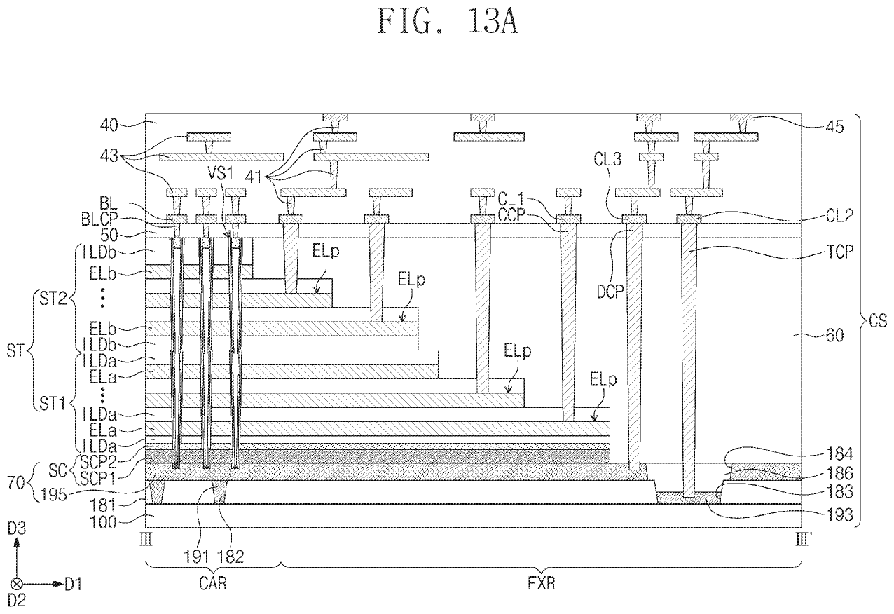

Referring to FIGS. 12A and 12B, a lower sacrificial layer 101 and a lower semiconductor layer 103 may be formed on the lower semiconductor layer 195. The lower semiconductor layer 103 may be formed by depositing a semiconductor material (e.g., poly silicon), which is doped to have a first conductivity type (e.g., n-type). The lower sacrificial layer 101 may be formed of or include, for example, silicon nitride. In an embodiment, the lower sacrificial layer 101 may be formed to have a multi-layered structure including a plurality of insulating layers.

First interlayer dielectric layers 111 and first sacrificial layers 121 may be alternatingly stacked on the lower semiconductor layer 103. Thereafter, the first vertical channel holes CH1 may be formed to penetrate the first interlayer dielectric layers 111 and the first sacrificial layers 121, and sacrificial layers may be formed to fill the first vertical channel holes CH1. Second interlayer dielectric layers 112 and second sacrificial layers 122 may be alternatingly stacked on the first vertical channel holes CH1. The first and second sacrificial layers 121 and 122 may be formed of or include an insulating material that is different from the first and second interlayer dielectric layers 111 and 112. The first and second sacrificial layers 121 and 122 may be formed of a material that can be etched with an etch selectivity with respect to the first and second interlayer dielectric layers 111 and 112. For example, the first and second sacrificial layers 121 and 122 may be formed of or include silicon nitride, and the first and second interlayer dielectric layers 111 and 112 may be formed of or include silicon oxide. Each of the first and second sacrificial layers 121 and 122 may have substantially the same thickness, and thicknesses of the first and second interlayer dielectric layers 111 and 112 may vary depending on their vertical position.

Thereafter, the second vertical channel holes CH2 may be formed to penetrate the second interlayer dielectric layers 112 and the second sacrificial layers 122 and to expose the sacrificial layers in the first vertical channel holes CH1. The second vertical channel holes CH2 may be overlapped with the first vertical channel holes CH1 in the third direction D3 and may be connected to the first vertical channel holes CH1 to constitute the vertical channel holes CH. The sacrificial layers, which are exposed through the second vertical channel holes CH2, may be removed, and then, the first to third vertical channel structures VS1, VS2, and VS3 may be formed in the vertical channel holes CH. Accordingly, the first and second interlayer dielectric layers 111 and 112 and the first and second sacrificial layers 121 and 122, which are alternately stacked on the lower semiconductor layer 103, may constitute the preliminary stack STp. The formation of each of the first to third vertical channel structures VS1, VS2, and VS3 may include forming the data storage pattern DSP and the vertical semiconductor pattern VSP to conformally cover an inner side surface of each of the vertical channel holes CH, forming the gap-fill insulating pattern VI in a space enclosed by the vertical semiconductor pattern VSP, and forming the conductive pad PAD in a space enclosed by the gap-fill insulating pattern VI and the data storage pattern DSP. The first to third vertical channel structures VS1, VS2, and VS3 may have top surfaces that are substantially coplanar with a top surface of the uppermost one of the second interlayer dielectric layers 112 and a top surface of the fourth interlayer insulating layer 60.

A trimming process may be performed on the preliminary stack STp, which includes the first and second interlayer dielectric layers 111 and 112 and the first and second sacrificial layers 121 and 122 that are alternately stacked. The trimming process may include forming a mask pattern on the cell array region CAR and the cell array contact region EXR to cover a portion of a top surface of the preliminary stack STp, patterning the preliminary stack STp using the mask pattern as a patterning mask, reducing an area of the mask pattern, and patterning the preliminary stack STp using the mask pattern of the reduced area. In an embodiment, the steps of reducing the area of the mask pattern and patterning the preliminary stack STp using the mask pattern may be repeated several times during the trimming process. As a result of the trimming process, each of the first and second interlayer dielectric layers 111 and 112 may be at least partially exposed to the outside, and the preliminary stack STp may have a staircase structure on the cell array contact region EXR. The staircase structure of the preliminary stack STp may be formed such that a portion of the lower semiconductor layer 195 and the contact pad 193 are exposed to the outside. Thereafter, the fourth interlayer insulating layer 60 may be formed to cover the staircase structure of the preliminary stack STp. In an embodiment, the fourth interlayer insulating layer 60 may be formed of or include silicon oxide.

The formation of the vertical channel holes CH may include an etching process capable of forming holes in a high aspect ratio. In this case, due to plasma in the etching process, an arcing phenomenon may occur, but the back-side via 191 may be used as a conduction path of exhausting charged particles, which cause the arcing phenomenon, to the outside through the carrier substrate 100.

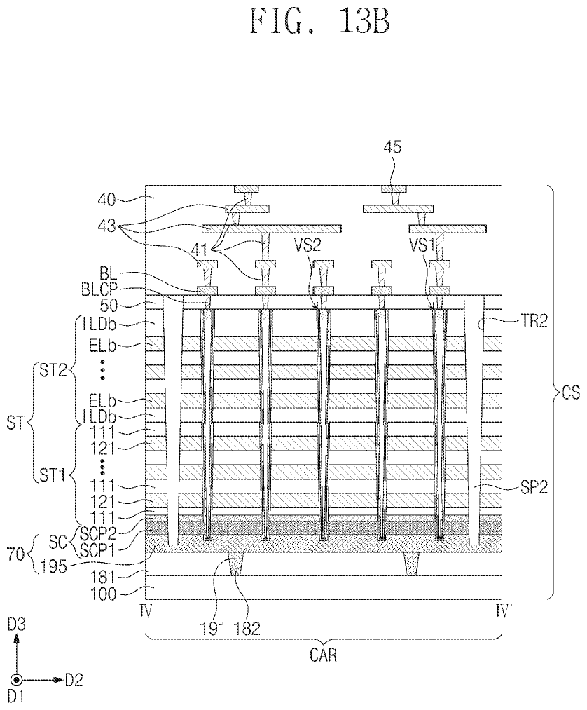

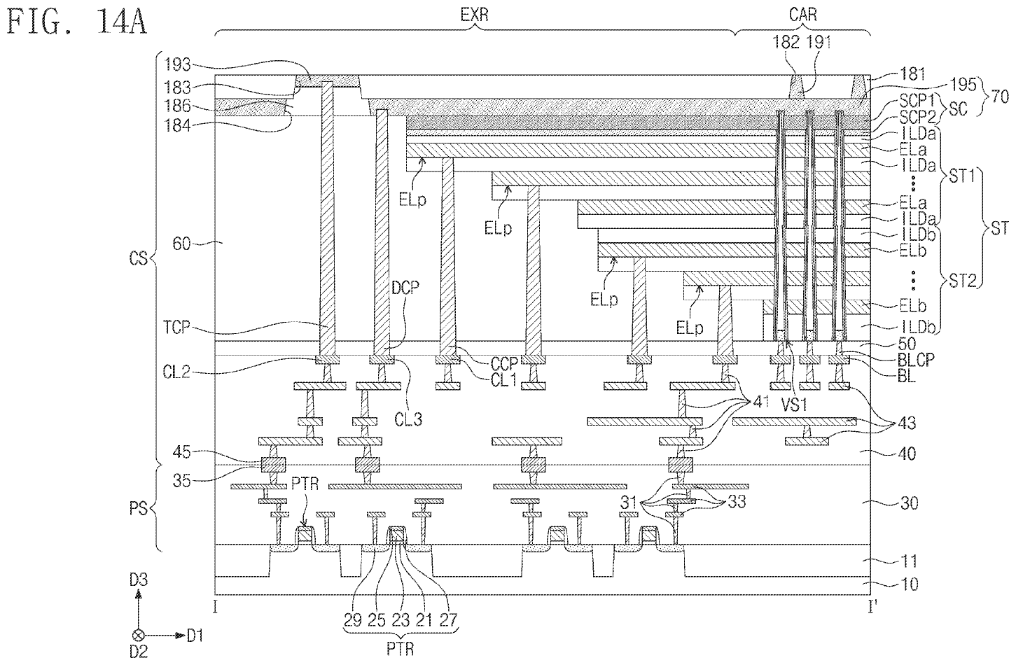

Referring to FIGS. 5, 13A, and 13B, the third interlayer insulating layer 50 may be formed to cover the top surface of the fourth interlayer insulating layer 60. The first and second trenches TR1 and TR2 may be formed to penetrate the third interlayer insulating layer 50, the preliminary stack STp, the lower semiconductor layer 103, the lower sacrificial layer 101, and at least a portion of the lower semiconductor layer 195. The first and second trenches TR1 and TR2 may be extended from the cell array region CAR to the cell array contact region EXR. A depth of the first trench TR1 may be smaller than a depth of the second trench TR2. A bottom surface of the first trench TR1 may be located at a level that is higher than the top surface of the topmost one of the first interlayer dielectric layers 111. A bottom surface of the second trench TR2 may be located at a level that is lower than the bottom surfaces of the first to third vertical channel structures VS1, VS2, and VS3.

The first and second sacrificial layers 121 and 122 and the lower sacrificial layer 101, which are exposed through the first and second trenches TR1 and TR2, may be removed. The removing of the first and second sacrificial layers 121 and 122 and the lower sacrificial layer 101 may be performed through a wet etching process using hydrofluoric acid (HF) and/or phosphoric acid (H₃PO₄) solution.

The data storage pattern DSP of each of the first and second vertical channel structures VS1 and VS2, which is exposed through an empty space formed by removing the lower sacrificial layer 101, may be partially removed, when the lower sacrificial layer 101 is removed.

The first source conductive pattern SCP1 may be formed to fill the empty space formed by removing the lower sacrificial layer 101. The first source conductive pattern SCP1 may be in contact with the vertical semiconductor pattern VSP of each of the first and second vertical channel structures VS1 and VS2. In an embodiment, the first source conductive pattern SCP1 may be formed of or include at least one of doped semiconductor materials. Although not shown, a void or a cavity (e.g., an air gap) may be formed in the first source conductive pattern SCP1. The lower semiconductor layer 103 may be referred to as the second source conductive pattern SCP2, and the source structure SC including the first and second source conductive patterns SCP1 and SCP2 may be formed. As a result, the second substrate 70 including the source structure SC and the lower semiconductor layer 195 may be formed.

The first and second gate electrodes ELa and ELb may be formed to fill empty regions formed by removing the first and second sacrificial layers 121 and 122. The first and second interlayer dielectric layers 111 and 112 may be referred to as the first and second interlayer dielectric layers ILDa and ILDb of the first and second stacks ST1 and ST2, and as a result, the stack ST including the first and second interlayer dielectric layers ILDa and ILDb and the first and second gate electrodes ELa and ELb may be formed.

The first separation pattern SP1 and the second separation pattern SP2 may be formed to fill the first trench TR1 and the second trench TR2, respectively. The first and second separation patterns SP1 and SP2 may be formed to have top surfaces that are substantially coplanar with a top surface of the third interlayer insulating layer 50.

In the cell array region CAR, the bit line contact plugs BLCP may be formed to penetrate the third interlayer insulating layer 50 and to be in contact with the top surfaces of the first and second vertical channel structures VS1 and VS2. In the cell array contact region EXR, the cell contact plugs CCP may be formed to penetrate the third and fourth interlayer insulating layers 50 and 60 and to be in contact with the pad portions ELp of the first and second gate electrodes ELa and ELb. Each of the cell contact plugs CCP may be formed to penetrate at least a portion of a corresponding one of the first and second interlayer dielectric layers ILDa and ILDb. In the cell array contact region EXR, the source contact plug DCP may be formed to penetrate the third and fourth interlayer insulating layers 50 and 60 and to be connected to the lower semiconductor layer 195. In the cell array contact region EXR, the penetration contact plug TCP may be formed to penetrate the third and fourth interlayer insulating layers 50 and 60 and to be connected to the contact pad 193.

At least two plugs of the cell contact plugs CCP, the source contact plug DCP, and the penetration contact plug TCP may be formed together (e.g., formed using the same process). The formation of the cell contact plugs CCP, the source contact plug DCP, and the penetration contact plug TCP may include an etching process for forming holes, which are formed to penetrate the third and fourth interlayer insulating layers 50 and 60 and thus have a high aspect ratio. A plasma-induced arcing phenomenon may occur in such an etching process, and the back-side via 191 and the contact pad 193 may be used as a conduction path for exhausting charged particles, which cause the arcing phenomenon, to the outside through the carrier substrate 100. In an embodiment, the contact pad 193 may also be used as an etch stop layer in the etching process for forming the contact hole.

In the cell array region CAR, the bit lines BL may be formed on the third interlayer insulating layer 50 to be in contact with the bit line contact plugs BLCP. In the cell array contact region EXR, the first to third conductive lines CL1, CL2, and CL3 may be formed on the third interlayer insulating layer 50.

The connection contact plugs 41, the connection circuit interconnection lines 43, and the second bonding pads 45, which are electrically connected to the bit lines BL and the first and second conductive lines CL1 and CL2, and the second interlayer insulating layer 40 covering them may be formed on the third interlayer insulating layer 50. The second bonding pads 45 may be formed to have top surfaces that are substantially coplanar with a top surface of the second interlayer insulating layer 40. Accordingly, the cell array structure CS may be formed on the carrier substrate 100.

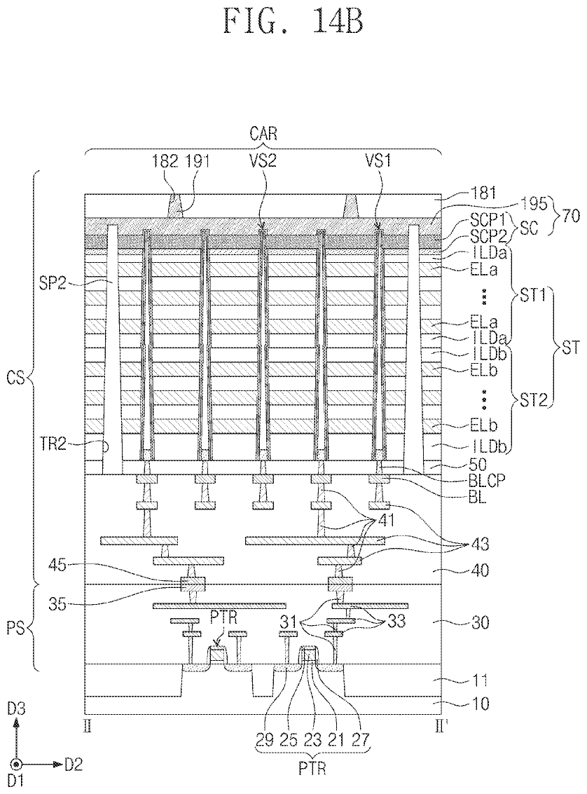

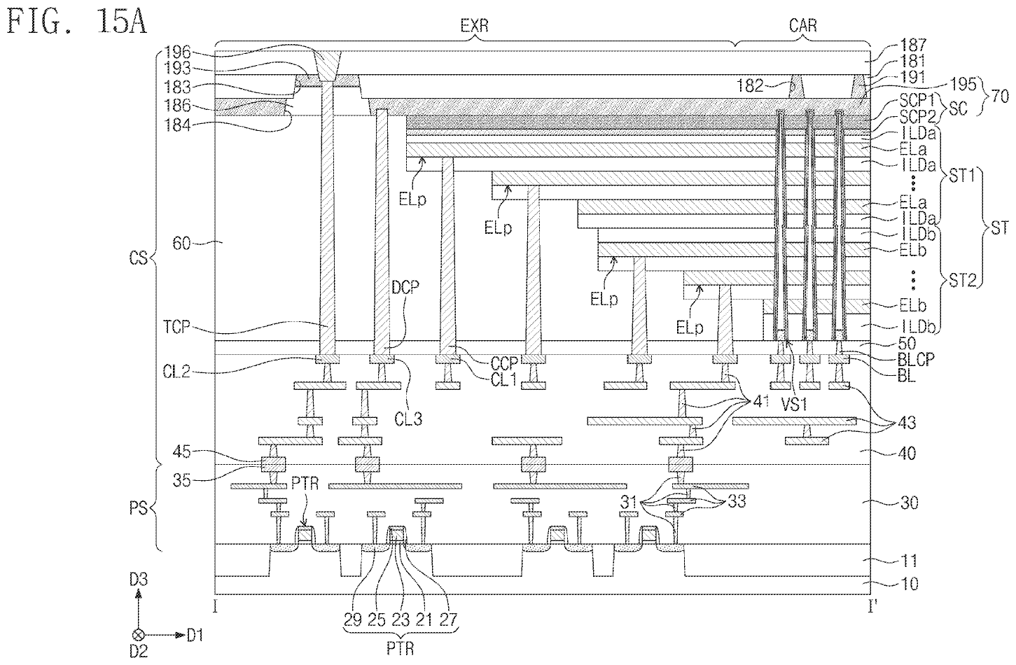

Referring to FIGS. 14A and 14B, the cell array structure CS, which is formed on the carrier substrate 100, may be bonded to the peripheral circuit structure PS, which is formed on the first substrate 10 by the method described with reference to FIGS. 8A and 8B. In detail, the cell array structure CS may be attached to the peripheral circuit structure PS such that a first surface of the first substrate 10, on which the peripheral circuit structure PS is formed, faces a first surface of the carrier substrate 100, on which the cell array structure CS is formed.

The carrier substrate 100 may be provided on the first substrate 10 such that the cell array structure CS and the peripheral circuit structure PS face each other. The peripheral circuit structure PS and the cell array structure CS may be bonded to each other by the first bonding pads 35 and the second bonding pads 45, which are in contact with each other and are fused into one. After the bonding of the first and second bonding pads 35 and 45, the carrier substrate 100 on the cell array structure CS may be removed. Accordingly, the back-side via 191 and the contact pad 193 may be exposed.

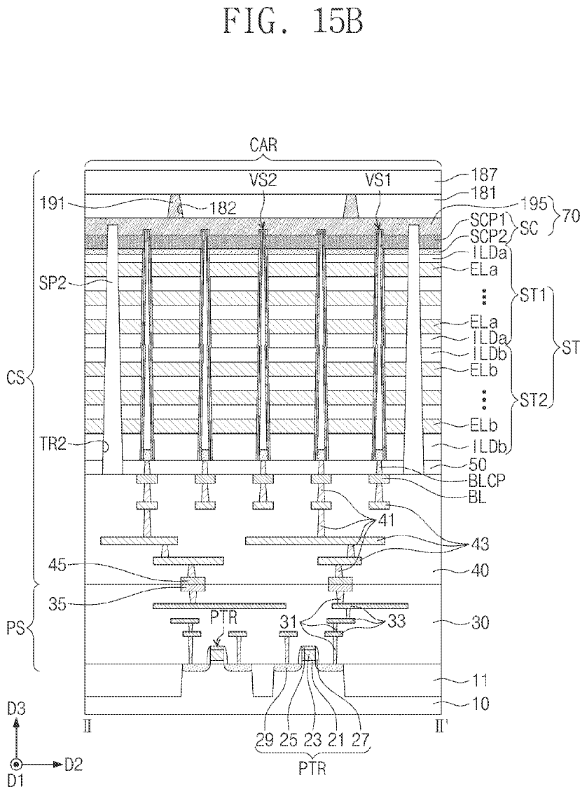

Referring to FIGS. 15A and 15B, the sixth interlayer insulating layer 187 may be formed on the fifth interlayer insulating layer 181, and then, the penetration via 196 may be formed to penetrate the sixth interlayer insulating layer 187 and to be connected to the contact pad 193 and/or the penetration contact plug TCP. The penetration via 196 may be formed by forming a penetration hole to penetrate the sixth interlayer insulating layer 187 and filling the penetration hole with a metallic material. As an example, the penetration via 196 may be formed of at least one of tungsten, titanium, tantalum, and conductive metal nitrides thereof.

Referring back to FIGS. 5, 6A, and 6B, the back-side conductive pattern 197 may be formed on the penetration via 196. The formation of the back-side conductive pattern 197 may include forming a metal layer to cover the penetration via 196, forming a mask pattern to cover the metal layer, and patterning the metal layer using the mask pattern as an etch mask. In this case, a width of a bottom surface of the back-side conductive pattern 197 may be larger than a width of a top surface thereof. In an embodiment, the back-side conductive pattern 197 may be formed of aluminum. Thereafter, the seventh interlayer insulating layer 188 may be formed to cover the sixth interlayer insulating layer 187 and to expose the back-side conductive pattern 197.

According to an embodiment of the inventive concept, it may be possible to simultaneously form the back-side via 191, which is used to reduce or prevent the occurrence of an arcing phenomenon in a process of forming penetration holes of a high aspect ratio, and the contact pad 193, which is used as an etch stop layer. This may make it possible to simplify a process of fabricating a semiconductor memory device. In addition, the contact pad 193 may also be used to reduce or prevent the occurrence of the arcing phenomenon in the process of forming the penetration hole, and thus, electric and reliability characteristics of the semiconductor memory device may be further improved.

According to an embodiment of the inventive concept, it may be possible to simultaneously form a back-side via, which is used to reduce or prevent the occurrence of an arcing phenomenon in a process of forming penetration holes of a high aspect ratio, and a contact pad, which is used as an etch stop layer. This may make it possible to simplify a process of fabricating a semiconductor memory device. In addition, since the occurrence of the arcing phenomenon is reduced or prevented by the back-side via and the contact pad, electric and reliability characteristics of a semiconductor memory device may be improved.

While example embodiments of the inventive concept have been particularly shown and described, it will be understood by one of ordinary skill in the art that variations in form and detail may be made therein without departing from the scope of the attached claims.

1. A method of fabricating a three-dimensional semiconductor memory device, the method comprising:
forming a peripheral circuit structure on a first surface of a first substrate;
forming a cell array structure on a first surface of a second substrate; and
attaching the cell array structure to the peripheral circuit structure such that the first surface of the first substrate and the first surface of the second substrate face each other,
wherein the forming of the cell array structure comprises:
forming a back-side via and a preliminary contact pad on the first surface of the second substrate;
forming a semiconductor layer contacting top surfaces of the back-side via and the preliminary contact pad;
forming a hole extending through the semiconductor layer and exposing the preliminary contact pad and removing an upper portion of the preliminary contact pad, thereby forming a contact pad separated from the semiconductor layer;
forming a stack on the semiconductor layer;
forming a first insulating layer on the stack; and
forming a contact plug extending through the first insulating layer and being connected to the contact pad.

2. The method of claim 1, wherein the forming of the back-side via and the preliminary contact pad comprises:
forming a second insulating layer on the second substrate:
forming a first hole and a second hole extending through the second insulating layer; and
forming the back-side via in the first hole and forming the preliminary contact pad in the second hole by forming a conductive material in the first hole and the second hole.

3. The method of claim 2, wherein the semiconductor layer is formed of the conductive material.

4. The method of claim 3, wherein the conductive material comprises poly silicon.

5. The method of claim 2, wherein the conductive material comprises tungsten, titanium, and/or tantalum, and
the semiconductor layer comprises poly silicon.

6. The method of claim 1, after the attaching the cell array structure to the peripheral circuit structure, further comprising:
removing the first substrate to expose the back-side via and the contact pad;
forming a third insulating layer on the back-side via and the contact pad; and
forming a via extending through the third insulating layer and being connected to the contact plug.

7. The method of claim 6, further comprising forming a back-side conductive pattern on the via.

8. The method of claim 6, wherein the via extends into the contact pad.

9. A method of fabricating a three-dimensional semiconductor memory device, the method comprising:
forming a peripheral circuit structure on a first surface of a first substrate;
forming a cell array structure on a first surface of a second substrate; and
attaching the cell array structure to the peripheral circuit structure such that the first surface of the first substrate and the first surface of the second substrate face each other,
wherein the forming of the cell array structure comprises:
forming a back-side via and a contact pad on the first surface of the second substrate;
forming a semiconductor layer on the back-side via and the contact pad;
forming a stack on the semiconductor layer;
forming a first insulating layer on the stack; and
forming a contact plug extending through the first insulating layer and being connected to the contact pad,
wherein the forming of the back-side via and the contact pad comprises:
forming a second insulating layer on the second substrate;
forming a first hole and a second hole extending through the second insulating layer; and
forming a conductive material in the first hole and the second hole.

10. The method of claim 9, wherein the forming of the cell array structure further comprises forming a third hole extending through the semiconductor layer and exposing the contact pad, and
during the forming of the third hole, an upper portion of the contact pad is removed such that the contact pad is spaced apart from the semiconductor layer.

11. The method of claim 9, wherein the semiconductor layer is formed of the conductive material.

12. The method of claim 9, wherein the conductive material comprises poly silicon.

13. The method of claim 9, wherein the conductive material comprises tungsten, titanium, and/or tantalum, and
the semiconductor layer comprises poly silicon.

14. The method of claim 9, after the attaching of the cell array structure to the peripheral circuit structure, further comprising:
removing the first substrate to expose the back-side via and the contact pad;
forming a third insulating layer on the back-side via and the contact pad; and
forming a via extending through the third insulating layer and being connected to the contact plug.

15. The method of claim 14, further comprising forming a back-side conductive pattern on the via.

16-30. (canceled)

31. A method of fabricating a semiconductor device, the method comprising:
forming a cell array structure on a substrate; and
attaching the cell array structure to a peripheral circuit structure, wherein the cell array structure is between the substrate and the peripheral circuit structure after the attaching,
wherein forming the cell array structure comprises:
forming a first insulating layer comprising a first hole and a second hole on the substrate, the first and second holes extending through the first insulating layer and exposing the substrate;
forming a back-side via in the first hole and a preliminary contact pad in the second hole by forming portions of a conductive layer respectively in the first and second holes;
forming a semiconductor layer extending on the first insulating layer and contacting the back-side via and the preliminary contact pad;
forming a third hole extending through the semiconductor layer and exposing the preliminary contact pad;
forming a contact pad by removing a portion of the preliminary contact pad through the third hole;
forming a stack on the semiconductor layer;
forming a second insulating layer on the stack; and
forming a contact plug extending through the second insulating layer and contacting the contact pad.

32. The method of claim 31, wherein the conductive layer comprises poly silicon.

33. The method of claim 31, wherein the back-side via contacts the substrate.

34. The method of claim 33, wherein forming the cell array structure further comprises forming a channel structure extending through the stack and contacting the semiconductor layer.

35. The method of claim 31, wherein the first insulating layer and the contact pad each comprise a lower surface facing the substrate and an upper surface opposite the lower surface, and
the upper surface of the contact pad is recessed toward the substrate relative to the upper surface of the first insulating layer.
